(19) United States
(12) Patent Application Publication
(10) Pub. No.: US 2015/0279456 A1
(43) Pub. Date: Oct. 1, 2015

(54) SEMICONDUCTOR MEMORY DEVICE AND FILE MEMORY SYSTEM

(71) Applicant: KABUSHIKI KAISHA TOSHIBA, Tokyo (JP)

(72) Inventor: Haruki TODA, Yokohama (JP)

(73) Assignee: KABUSHIKI KAISHA TOSHIBA, Tokyo (JP)

(21) Appl. No.: 14/736,896

(22) Filed: Jun. 11, 2015

Related U.S. Application Data
(62) Division of application No. 13/778,642, filed on Feb. 27, 2013.
(60) Provisional application No. 61/683,508, filed on Aug. 15, 2012.

(51) Int. Cl. G11C 13/00

(52) U.S. Cl. CPC G11C 13/003; G11C 13/004

(57) ABSTRACT

According to an embodiment, a semiconductor memory device has: a memory cell array formed by stacking through insulation layers a plurality of memory mats which each have a plurality of first lines, a plurality of second lines and a plurality of resistance varying memory cells provided at intersection portions of the pluralities of first lines and second lines; and an accessing circuit which applies voltages to the memory cell array. A number of the first lines included in the memory mat is greater than a number of the second lines. When the accessing circuit accesses the selected memory cell, the accessing circuit selects a plurality of first lines and a second line connected to selected memory cells to which the accessing circuit needs to be connected and judges data stored in the selected memory cells according to currents flowing to the selected memory cells.

### CROSS-REFERENCE TO RELATED APPLICATIONS

This application is a divisional of U.S. application Ser. No. 13/778,642, filed on Feb. 27, 2013, and is based upon and claims the benefit of U.S. Provisional Patent Application No. 61/683,508, filed on Aug. 15, 2012, the entire contents of each of which are incorporated herein by reference.

### BACKGROUND

1. Field

An embodiment disclosed herein relates to a semiconductor memory device and a file memory system.

2. Description of the Related Art

In recent years, electrically rewritable resistance varying memories such as ReRAMs and PRAMs are gathering attention as semiconductor memory devices. A memory cell of a resistance varying memory is configured to change a resistance value, and store data according to a change in this resistance value. Such a resistance varying memory is provided between a word line and a bit line. Further, the inventors propose a floating access method as an access method of a resistance varying memory.

### BRIEF DESCRIPTION OF THE DRAWINGS

FIG. 1 is a structural diagram of a memory cell array 1 of a semiconductor memory device according to a first embodiment;

FIG. 2 is a structural diagram of a peripheral circuit of the semiconductor memory device according to the first embodiment;

FIG. 3 is a circuit diagram of a memory cell array of a semiconductor memory device according to the first embodiment;

FIG. 4 is a schematic view for explaining a configuration and an operation of the memory cell of the semiconductor memory device;

FIG. 5 is a block diagram for explaining an arrangement of a data bus of the semiconductor memory device;

FIG. 6 is a circuit diagram for explaining a configuration of a decoder circuit of the semiconductor memory device;

FIG. 7 is a schematic plane view for explaining a layout of the decoder circuit of the semiconductor memory device;

FIG. 8 is a graph for explaining operation characteristics of a memory cell of the semiconductor memory device;

FIG. 9 is a circuit diagram for explaining a method of setting a potential according to a fixed potential method of the semiconductor memory device;

FIG. 10 is a circuit diagram for explaining a method of setting the potential in an active stand-by state when a FLA method is adopted for the semiconductor memory device;

FIG. 11 is a circuit diagram for explaining a state of the potential in a FLA final state when the FLA method is adopted for the semiconductor memory device;

FIG. 12 is a schematic view for explaining a configuration example of word lines of the semiconductor memory device;

FIG. 13 is a schematic view for explaining another configuration example of word lines of the semiconductor memory device;

FIGS. 14A and 14B are schematic plane views for explaining a difference between configuration examples of word lines of the semiconductor memory device;

FIG. 15 is a graph for explaining a transition of a dead-band voltage of the memory cell of the semiconductor memory device;

FIG. 16 is a graph for explaining a method of setting a potential for suppressing a dead-band voltage of the memory cell of the semiconductor memory device;

FIG. 17 is a circuit diagram for explaining a state of the potential in a hold state during a FLA operation when there is a short-circuited memory cell in a memory mat of the semiconductor memory device;

FIG. 18 is a circuit diagram for explaining a method of setting the potential in initial stand-by during the FLA operation when there is a short-circuited memory cell in the memory mat of the semiconductor memory device;

FIG. 19 is a circuit diagram for explaining a method of setting the potential in active stand-by during the FLA operation when there is a short-circuited memory cell in the memory mat of the semiconductor memory device;

FIG. 20 is a circuit diagram for explaining a state of the potential in the final state during the FLA operation when there is a short-circuited memory cell in the memory mat of the semiconductor memory device;

FIG. 21 is a schematic plane view for explaining a redundancy of the semiconductor memory device;

FIG. 22 is a circuit diagram illustrating a configuration of a current-comparing sense amplifier of the semiconductor memory device;

FIG. 23 is a waveform diagram illustrating an operation of the current-comparing sense amplifier;

FIG. 24 is a circuit diagram for explaining a configuration example of the sensing system of the semiconductor memory device;

FIG. 25 is a circuit diagram for explaining a configuration example of the current-comparing sense amplifier in the sensing system;

FIG. 26 is a circuit diagram for explaining another configuration example of the current-comparing sense amplifier in the sensing system;

FIG. 27 is a waveform diagram for explaining an example of a method of operating the sensing system;

FIG. 28 is a circuit diagram for explaining another configuration example of the sensing system of the semiconductor memory device;

FIG. 29 is a schematic plane view for explaining serial resistance areas of the semiconductor memory device;

FIG. 30 is a schematic side view for explaining a configuration of a serial resistance of the semiconductor memory device; and

FIG. 31 is a block diagram for explaining a memory system utilizing the semiconductor memory device.

### DETAILED DESCRIPTION

A semiconductor memory device according to the following embodiment has: a memory cell array which has a memory mat which has a plurality of first lines, a plurality of second lines intersecting with the first lines and a plurality of resistance varying memory cells provided at intersection portions of the pluralities of first lines and second lines; and an accessing circuit which accesses selected memory cells by applying voltages to the memory cell array. A number of the first lines included in the memory mat is greater than a number of the second lines. When the accessing circuit accesses the selected memory cell, the accessing circuit selects a plurality of first lines and a second line connected to selected memory cells to which the accessing circuit needs to be connected and judges data stored in the selected memory cells according to currents flowing to the selected memory cell.

Hereinafter, an embodiment of a semiconductor memory device will be described with reference to the drawings.

### First Embodiment

[1. Outline of Semiconductor Memory Device]

[1-1. Overall Configuration]

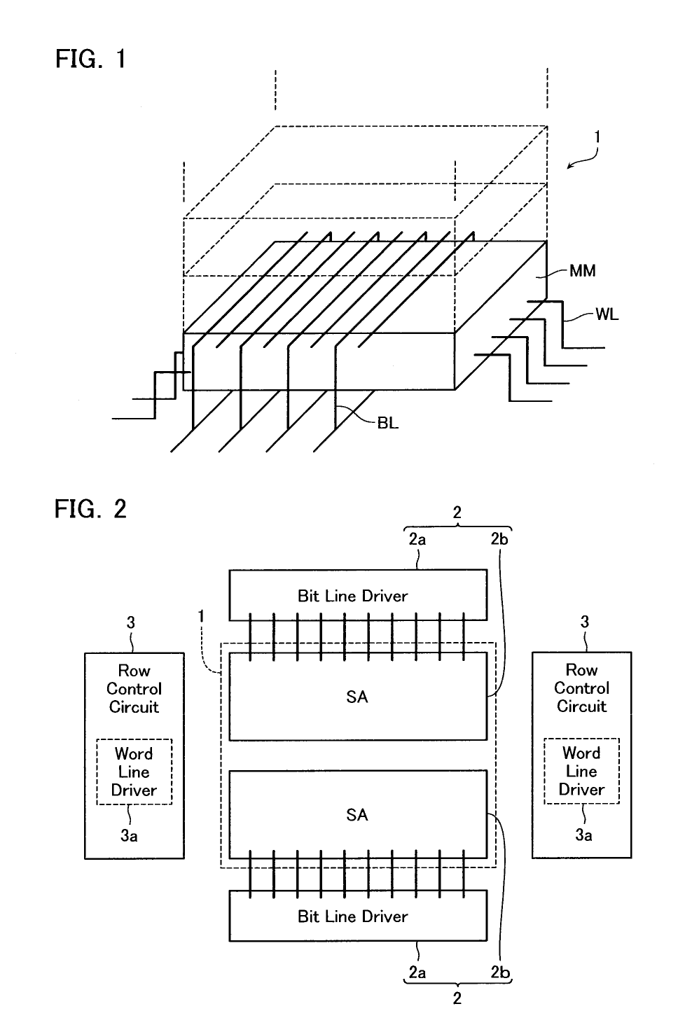

FIGS. 1 and 2 are structural diagrams of a semiconductor memory device according to an embodiment. This semiconductor memory device has a memory cell array 1, and further has a column control circuit 2 and a row control circuit 3 for controlling data erase, data write, and data read in this memory cell array 1.

The memory cell array 1 has a plurality of memory mats MM (memory cell layers) which are stacked through insulation layers. Each memory mat MM has a plurality of bit lines BL (first lines) and a plurality of word lines WL (second lines) which intersect each other, and a memory cell MC connected at each intersection position of the bit line BL and the word line WL. The bit lines BL and the word lines WL are arranged at virtually minimum pitches, and are led alternately from two opposing sides instead of one side of the memory cell mats MM and connected to the column control circuit 2 and the row control circuit 3 through vertical lines.

The column control circuit 2 is connected to the bit lines BL, and controls the bit lines BL to erase data in the memory cell MC, write data to the memory cell MC and read data from the memory cell MC. In addition, data erase in the memory cell MC is referred to as “reset”, and data write to the memory cell MC is also referred to as “set” below. Further, an erase operation, a write operation and a read operation are collectively referred to as an “access operation”. The column control circuit 2 has a bit line driver 2a which includes a decoder and a multiplexer which select the bit line BL and which supplies a voltage which is necessary for the access operation, to the bit line BL, and a sense amplifier 2b (SA) which detects and amplifies the current flowing to the memory cell MC upon the read operation and judges data stored in the memory cell MC. With the present embodiment, the bit line drivers 2a are formed in two opposing sides of an area directly below the memory cell array 1, and the sense amplifiers 2b are formed in the area directly below the memory cell array 1.

Meanwhile, the row control circuit 3 is connected to the word lines WL of the memory mat MM, and selects the word line WL upon the access operation. The row control circuit 3 has a word line driver 3a which includes a decoder and a mutliplexer which select the word line WL, and which supplies a voltage which is necessary for the access operation, to the word line WL. The word line drivers 3a are formed in two opposing sides of the area directly below the memory cell array 1. With the present embodiment, there is no line led from the word line driver 3a to the area directly below the memory cell array 1, and therefore a line area may be provided between the area directly below the memory cell array 1 and the word line driver 3a. In addition, this row control circuit 3 is included in an accessing circuit together with the column control circuit 2.

[1-2. Memory Cell Array]

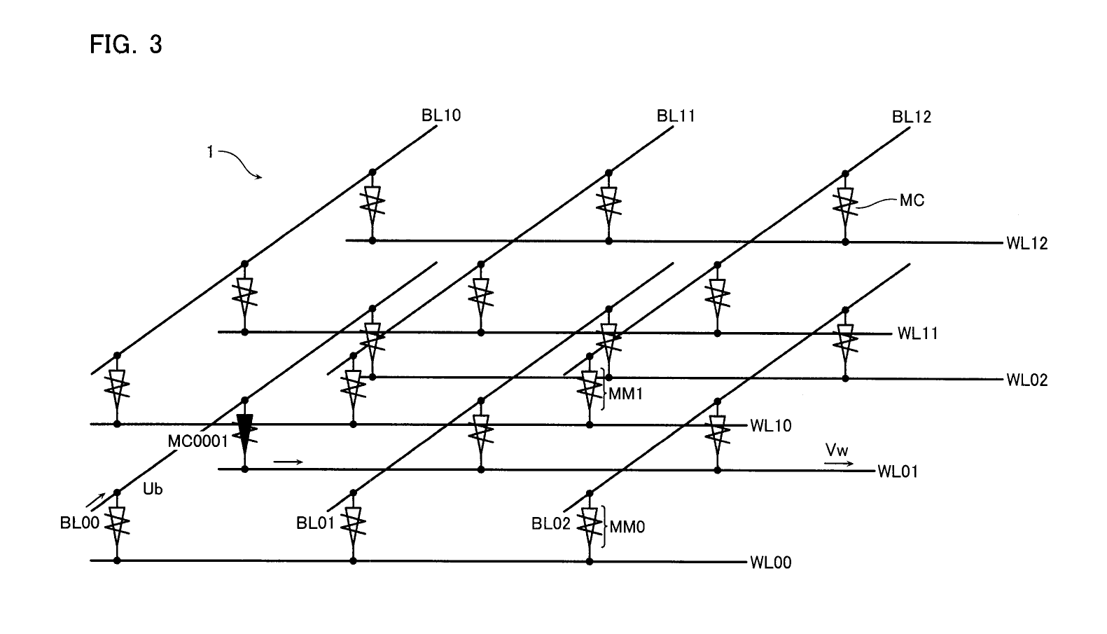

FIG. 3 is an equivalent circuit diagram of the memory cell array 1 illustrated in FIG. 2. As described in detail below, the memory cells MC show a variable resistance characteristic and a non-ohmic characteristic, and an orientation of a large current flow is shown by an elongated triangle. Therefore, a base end side of the triangle represents an anode, and a pointed side of the triangle represents a cathode. As illustrated in FIG. 3, current rectifying directions in the memory cells MC are all the same in the memory cell array 1.

Now, when accessing a memory cell MC0001 shown in FIG. 3, a bit line BL00 connected to an anode side of the memory cell MC0001 is supplied with a selected bit line voltage Ub, and a selected word line WL01 connected to a cathode side of the memory cell MC0001 is supplied with a selected word line voltage Vw. This results in a current flowing as indicated by the arrows in the drawing when, for example, Ub>Vw is true, so that access is performed. It is important how large voltage is provided to the bit lines BL and the word lines WL connected to the memory cells MC other than the selected memory cell MC0001, and it is required to enabling the selecting memory cell MC0001 to be reliably accessed. Because a floating access method (FLA) described below is adopted in this embodiment, a state of unselected bit lines and unselected word lines are all changed to a floating state.

[1-3. Memory Cell]

Next, the memory cell MC according to the present embodiment will be described. In addition, although a memory cell using CBRAM (Conduction Bridge RAM) will be described here as a representative resistance varying memory element, the configuration of the element does not matter provided that the element is an element of a kind capable of being changed between a low-resistance state and a high-resistance state according to an amplitude of a voltage applied thereto or a polarity of that voltage and capable of maintaining the resistance state to a certain extent. Further, although a resistance varying element alone does not necessarily show sufficient asymmetric current characteristics with respect to the polarity of the applied voltage and, therefore, a configuration which actively employs a configuration having diode characteristics will be studied, as long as a resistance varying element shows diode characteristics without a diode characteristic element in particular, this characteristic portion may be separated and regarded as a diode.

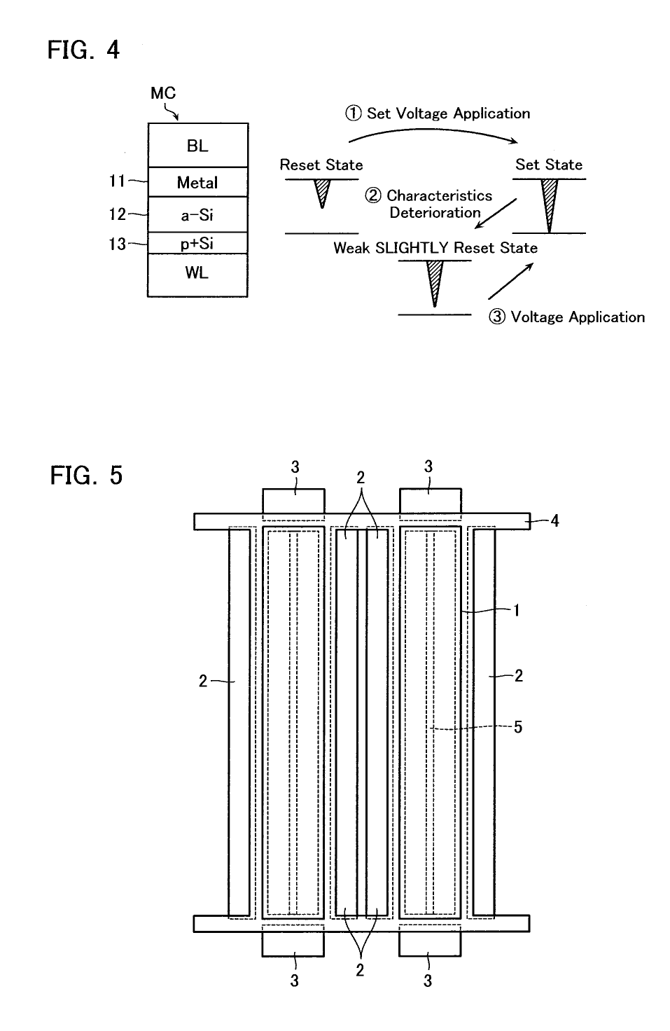

FIG. 4 is a view illustrating a configuration and states of the memory cell MC according to the embodiment. As illustrated in the leftmost schematic structural diagram of FIG. 4, the memory cell MC includes a metal layer 11, an amorphous silicon layer 12, and a p-type doped polysilicon layer 13 arranged between the bit lines BL and the word lines WL in order from the bit line BL. The metal layer 11 functions as a generation source of metal ions. The amorphous silicon layer 12 becomes a medium for filaments of metal to grow. In addition, a n-type doped polysilicon layer may also be formed between the amorphous silicon layer 12 and the word lines WL instead of the p-type doped polysilicon layer 13, or the p-type doped silicon layer 13 may also be removed simply. In addition, a diode may also be formed between the amorphous silicon layer 12 and the word line WL.

In addition, although the amorphous silicon layer 12 is used in the configurative diagram of FIG. 4, a layer is not limited to a semiconductor and may be an insulation film such as a silicon oxide (SiOx), silicon oxynitride (SiOxNy), silicon nitride (SiNx) or metal oxide film. Further, the amorphous silicon layer 12 may adopt a stacked structure of these insulation films such as a stacked structure of amorphous silicon and silicon oxide. Furthermore, word line WL in the configurative diagram of FIG. 4 only needs to function as an electrode, and may be a p-type doped polysilicon or an n-type doped polysilicon or may be metal.

The right side of the configurative diagram in FIG. 4 illustrates schematic views of some cell states as views schematically expressing states and a configuration of this memory cell MC. A metal filament is shown by a downwardly directed vertically long triangle. Further, the memory cell MC is provided with an anode on the bit line BL side and a cathode on the word line WL side.

In the memory cell MC in the reset state, a filament formed in the memory cell MC does not penetrate the amorphous silicon layer 12 and is in a high resistance state. When a forward set voltage is applied to the memory cell MC in such a reset state, the filament penetrates the amorphous silicon layer 12 and transition to the set state, that is, a low resistance state. Applying a set voltage to a memory cell MC in the reset state and changing the memory cell MC to the set state will be referred to as a “set operation” below. Further, a state in which a filament is about to contact the amorphous silicon layer 12 will be referred to as a “weak reset state” below.

[1-4. Data Bus]

A data bus 4 around the memory cell array 1 will be described with reference to FIG. 5. The data bus 4 is integrally formed with the column control circuits 2 and the row control circuits 3, and is formed along four sides of the memory cell array 1. In addition, the data bus 4 transfers not only data read from the memory cell MC but also address data of the selecting memory cell MC. Further, a data bus 5 extending in a row direction is arranged below the memory cell array 1. The data bus 5 transfers, for example, a signal for controlling the sense amplifier 2b and data to be written in the memory cell MC.

[1-5. Column Control Circuit and Row Control Circuit]

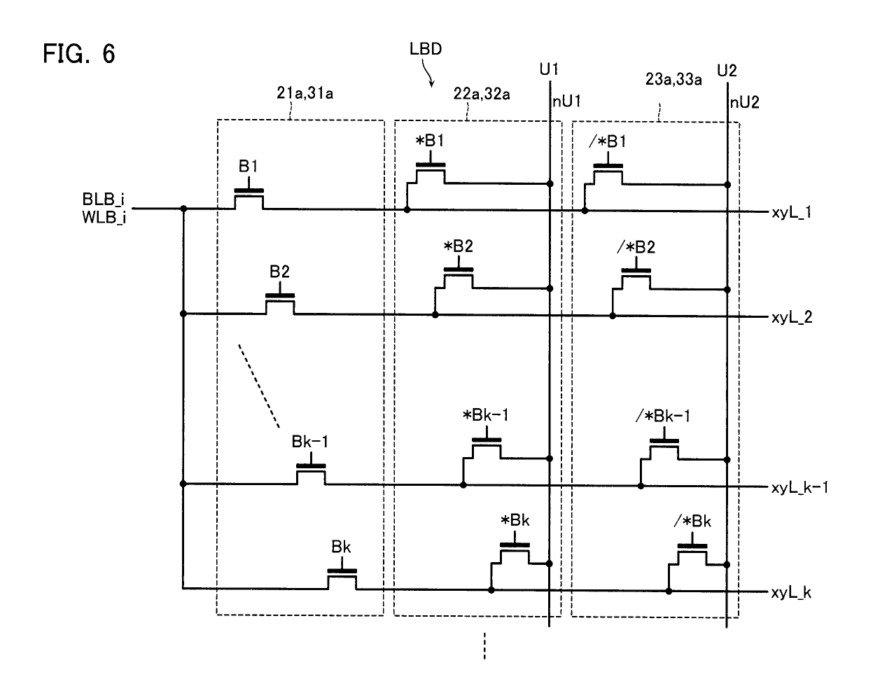

FIG. 6 is a circuit diagram illustrating a configuration example of the bit line driver 2a and the word line driver 3a. The bit line driver 2a and the word line driver 3a are each configured to have a plurality of selecting line block decoders LBD. In addition, the number of the selecting line block decoders LBD included in the bit line drivers 2a is the same as the product of the total number of the memory mat MM configuring the memory cell array 1 and the number of bit line blocks BLB configured by the plurality of bit lines BL, and the number of selecting line block decoders LBD included in the word line driver 3a is the same as the product of the total number of the memory mat MM configuring the memory cell array 1 and the number of word line blocks WLB configured by the plurality of word lines WL. “xyL” of xyL_1 to xyL_k in FIG. 6 represents a bit line “BL” or a word line “WL”.

In the selecting line block decoder LBD, a plurality of bit lines BL or word lines WL (referred to as “selecting lines xyL” below) configuring a bit line block BLB or a word line block WLB (referred to as “selecting line block LB” below) are each connected with a sense node BLB_i or WLB_i, a selected potential supply node nU1 and an unselected potential supply node nU2 through NMOS transistors, and form selector units 21a and 31a which each select one selecting line xyL and connect to the sense node BLB_i or WLB_i, selected potential units 22a and 32a which supply the voltage to the selecting line xyL which is selected and unselected potential units 23a and 33a which supply the voltage to the selecting line xyL which is not selected.

A plurality of NMOS transistors configuring the selected potential units 22a and 32a have their respective gates inputting address signals “*B1” to “*Bk”, and by having only one of the address signals at “H”, connect one of the selecting lines xyL to the selecting line potential supply node nU1 to charge the selecting line xyL to a selecting potential U1 in advance.

A plurality of NMOS transistors configuring the unselected potential units 32a and 33a have their respective gates inputting address signals “/*B1” to “/*Bk”, and by having the address signal corresponding to the selecting lines xyL unselected by the selected potential units 22a and 32a at “H”, charges the unselected selecting line xyL to the unselected potential U2.

Next, the address signals “*B1” to “*Bk” and the address signals “/*B1” to “/*Bk” all become “L” and, instead, the address signals “B1” to “Bk” are inputted to gates of a plurality of NMOS transistors configuring the selector units 21a and 31a, so that one of the address signals “B1” to “Bk” corresponding to one of the address signals “*B1” to “*Bk” selected by the selected potential units 22a and 32a become “H”. As a result, the one selected selecting line xyL is connected to the sense node BLB_i or WLB_i, and the unselected selecting lines xyL are changed to floating states.

The address signals “B1” to “Bk”, the address signals “*B1” to “*Bk” and the address signals “/*B1” to “/*Bk” are commonly connected to all selecting line block decoders LBD arranged in the row direction in the bit line driver 2a or all selecting line block decoders LBD arranged in the column direction in the word line driver 3a.

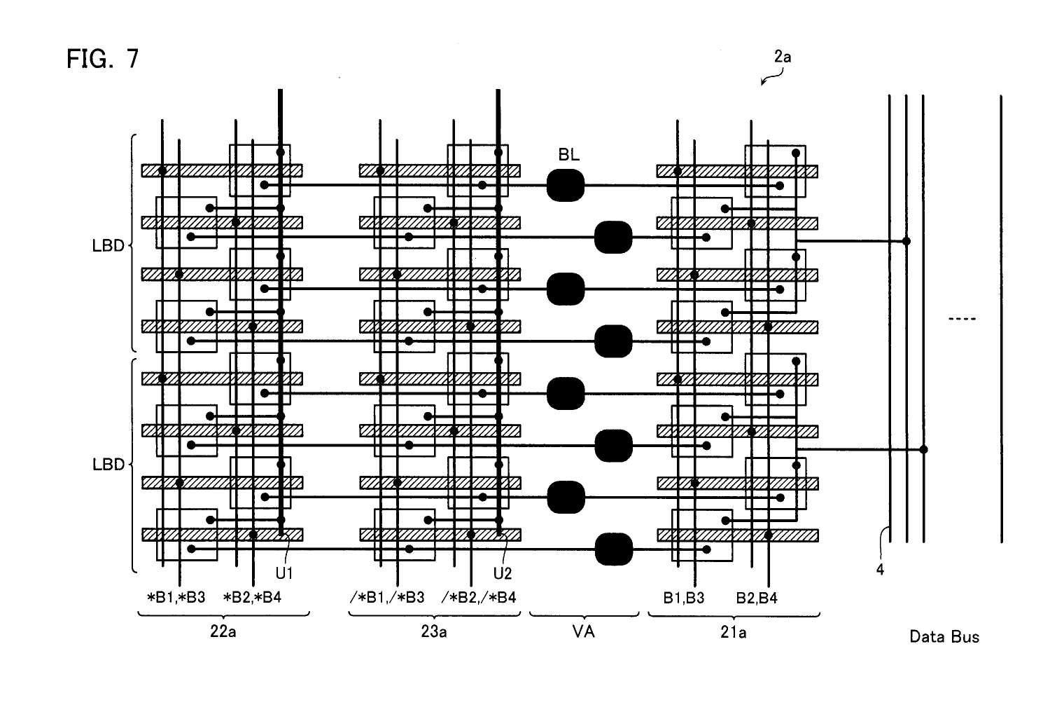

Next, an example of a layout of the selecting line block decoders LBD will be described. FIG. 7 is a plan view illustrating an example of a layout of the selecting line block decoders LBD. In addition, although a selecting line block decoder LBD in the bit line driver 2a is focused upon with this example, the word line driver 3a can also employ the same configuration. Further, the number of bit lines k configuring the bit line block BLB is 4. In addition, when a configuration of leading the bit lines BL alternately from both sides of the memory mat MM is assumed, the selecting line block decoder LBD occupies an area corresponding to the number of bit lines BL. Further, in the bit line driver 2a, the number of the selecting line block decoders LBD arranged in the column direction is the same as the number of memory mats MM configuring the memory cell array 1, and the number of the selecting line block decoders LBD arranged in the row direction is the same as the bit line blocks BLB in the memory mat MM. In addition, the selecting line block decoder LBD corresponding to each memory mat MM can independently operate.

As illustrated in FIG. 7, in the selecting line block decoder LBD, for example, the selector unit 21a, a vertical line area VA, the unselected potential unit 23a and the selected potential unit 22a are arranged in order closer to the data bus 4. A plurality of transistors configuring the selecting line block decoder LBD includes a semiconductor which operates as a source, a drain and a channel, and a metal layer which operates as a gate.

[2. Increase in Memory Size of Memory Cell Array]

As all current rectifying directions of the memory cells MC are the same in the present embodiment, process integration of the memory cell array 1 can be simplified, and the short-circuited memory cell MC is easily handled. Increasing memory size of the memory cell array 1 according to the present embodiment will be described.

[2-1. Reduction in Leak Current]

When a scale of the memory cell array 1 becomes larger, a leak current may increase. An increase in the leak current causes an error operation and an increase in power consumption, and therefore reduction of the leak current is an important task to increase memory size of the memory cell array 1. Leak currents in the memory mats MM and leak currents in the overall memory cell array 1 formed by stacking a plurality of memory mats MM will be described below using a set operation as an example.

[2-1-1. Reduction in Leak Current in Memory Mat]

A relationship between a voltage applied to the memory cell MC and a current flowing through the memory cell MC at the voltage will be described, and then a leak current and reducing methods thereof in case that an access to the memory cell array 1 is made according to the fixed potential method and according to the FLA (floating access) method will be described.

[(1) Relationship Between Current and Voltage of Memory Cell MC]

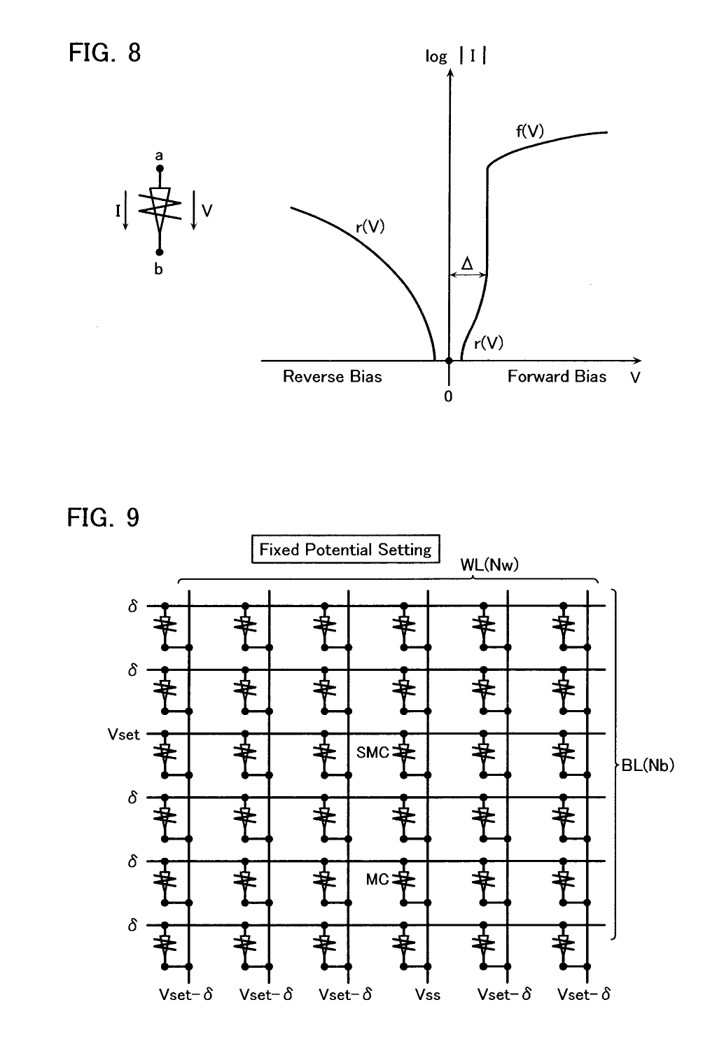

FIG. 8 is a graph illustrating a relationship between a current and a voltage of the memory cell MC in the set state. The horizontal axis indicates a bias voltage to be applied to the memory cell MC, and the vertical axis indicates an absolute value of a cell current (logarithmic value) flowing through the memory cell MC. Hence, the current flows in a minus direction when a reverse bias is applied to the memory cell MC. Further, as a tendency of a change in the cell current is important upon study of the leak current, units are indicated by arbitrary scales.

As illustrated in FIG. 8, when a reverse voltage is applied to the memory cell MC in the set state, a current at such a level that the current can be ignored upon an access operation flows. Hereinafter, this current is represented as I=r(V). When a forward voltage is applied to the memory cell MC in the set state, the same cell current I=r(V) flows as in case that the reverse bias is applied if the amplitude of the voltage is less than the forward dead-band voltage Δ. In addition, a value of the dead-band voltage Δ changes depending on whether or not the memory cell MC in the set state, the reset state or the weak reset state. This dead-band voltage Δ can be controlled by applying the reverse voltage to the memory cell MC. When the voltage applied to the memory cell MC is the dead-band voltage Δ or more, the amount of current flowing through the memory cell MC increases over several digits. Hereinafter, a current flowing through the memory cell MC incase that the voltage equal to or more than the dead-band voltage Δ is applied in the forward direction in the set state is represented as I=f(V). The memory cell MC can be regarded to be in the high resistance state until the voltage exceeds the dead-band voltage Δ, and a value of the dead-band voltage Δ is an important factor.

In addition, although characteristics of the memory cell MC in the reset state are not illustrated, the memory cell MC in the reset state shows characteristics in which the dead-band voltage Δ is increased up to the set voltage Vset in the graph of FIG. 8.

[(2) Leak Current in Fixed Potential Method]

Next, a leak current according to the access operation using the fixed potential method, that is, a method of setting an unselected bit line voltage and an unselected word line voltage to a fixed potential will be described. FIG. 9 illustrates a voltage applied to each bit line BL and word line WL according to the fixed potential method. When the set operation is performed with respect to, for example, a selected memory cell SMC according to the fixed potential method, a set voltage Vset is applied to the selected bit line BL and a ground voltage Vss is applied to the selected word line WL. Here, Vss and Vset can be applied to the unselected bit lines BL and the unselected word lines, respectively. However, it is possible to reduce the leak current when a reverse bias voltage to be applied to the unselected memory cell MC is smaller. Therefore, a potential δ a little higher than the ground potential Vss is applied to the unselected bit line BL and a voltage Vset-δ a little lower than the set voltage Vset is applied to the unselected word line WL. Further, it is also necessary to suppress the leak current of the unselected memory cell MC to which a forward bias voltage is applied, and therefore the voltage 8 is set to the dead-band voltage Δ or less. In addition, individual differences between the unselected bit lines BL and the unselected word lines WL are ignored, and the same potential is set to each line. That is, it is assumed that the voltage δ has certain given fixed voltage value.

Here, it is assumed that: the total number of bit lines BL configuring one memory mat MM is Nb; the total number of word lines WL is Nw; the total number of bit lines accessed at the same time (referred to as “the accessed bit lines” below) is B; and the number of word lines to access at the same time is 1.

If the voltage is applied to each bit lines BL and word lines WL, there are (Nb−B) (Nw−1) unselected memory cells MC connected to the unselected bit lines BL and the unselected word lines WL. A voltage Vset−2δ is applied to these unselected memory cells MC in a reverse direction and a reverse leak current is produced. Meanwhile, the number of unselected memory cells MC connected to the unselected bit lines BL and the selected word line WL and the number of unselected memory cells MC connected to the selected bit lines BL and the unselected word lines WL are Nb−B+(Nw−1)B in total. The voltage δ is applied to these memory cells MC in the forward direction, and a forward leak current is produced. Hence, when a total leak current flowing to the bit lines BL is Ib, Ib=r(Vset−2δ)·(Nb−B)(Nw−1)−r(δ)·(Nb−B)−r(δ)·B(Nw−1)=r(Vset−2δ)·Nb(Nw−1)−r(δ)·Nb−{r(δ)·(Nw−2)+r(Vset−2δ)·(Nw−1)}B is true. Further, when the total leak current flowing to the word lines WL is Iw, there is no power supply in the memory mats MM, and Ib+Iw=0 is true.

According to the fixed potential method, the unselected word line voltage is set higher than the unselected bit line voltage such that a reverse voltage is applied to the memory cells MC connected to the unselected bit lines BL and the unselected word lines WL, and therefore a power consumption component of the leak current is the current Ib flowing from the word line WL side to the bit line BL side. Consequently, it is possible to reduce the leak current by reducing the above M.

To reduce the above Ib, it is possible to set the first term of the above equation smaller, and set the second term and the third term larger. First, setting the first term smaller will be described. When a memory size of a memory cell array is increased, Nb(Nw−1) increases. Consequently, to set the first term smaller, it may be possible to set r(Vset−2δ) smaller. While it may be possible to set 6 larger to set r(Vset−2δ) smaller, it is not possible to set δ larger than the dead-band voltage Δ. Therefore, δ is set to virtually an equal value to the dead-band voltage Δ. Meanwhile, attention needs to be paid to an increase of a current value over several digits when 6 exceeds the dead-band voltage Δ. Next, setting the second term and the third term larger will be described. To enlarge the second term, it may be possible to increase the total number of bit lines Nb. Further, to enlarge the third term, it may be possible to increase the number of access bit lines B.

In addition, Nw−1 unselected word lines WL are connected to each of the selected bit lines BL through the unselected memory cell MC, and a leak current of r(δ) flows out from each of the unselected word lines. Hence, a current of r(δ)(Nw−1) flows out from each selected bit line BL. Consequently, it is possible to reduce a sense noise current in the selected bit line BL by reducing the Nw.

In view of above, when the fixed potential method is adopted to access the memory cell MC, the next point is desirably taken into account to increase the memory size of the memory cell array.

(a) It is possible to reduce the leak current by increasing the total number of bit lines Nb and the number of access bit lines B in the memory mat MM.
(b) It is possible to reduce the sense noise current by decreasing the total number of word lines Nw. It is considered that the total number of bit lines Nb may be set at least larger than the total number of word lines Nw.

(c) A consumption current significantly fluctuates following variation in the dead-band voltages between the memory cells MC.
[(3) Leak Current in FLA Method]

Next, a leak current according to the access operation using the FLA method, that is, according to a method of setting unselected bit lines and unselected word lines to floating states will be described. When the FLA method is used, it is possible to reduce power consumption compared to using the fixed potential method. Further, although a consumption current significantly fluctuates following variation in the dead-band voltage Δ of the memory cell MC according to the fixed potential method, it is possible to avoid such a problem according to the FLA method.

When an access operation is not performed with respect to the memory cell MC in a given memory mat MM, potentials of all bit lines BL and word lines WL in the memory mat MM are set to the ground potential Vss. This state is referred to as a “hold state”. When the access operation is started according to the FLA method, an initial stand-by operation and an active stand-by operation are performed by applying a predetermined fixed voltage to each of the bit lines BL and the word lines WL. Then a main access operation is performed by applying the fixed voltage to the selected bit line BL and the selected word line WL and making the unselected bit lines BL and the unselected word lines WL to the floating state. Hereinafter, leak currents during the initial stand-by operation, during the active stand-by operation and during the main access operation will be described.

[(3-1) Leak Current During Initial Stand-By Operation]

In the initial stand-by operation, the dead-band voltage Δ of the memory cell MC is applied to all Nb bit lines BL. Further, the voltage Vset−Δ is applied to all Nw word lines WL. Hence, the voltage (Vset−2Δ) is applied to all memory cells MC in the memory mat MM in the reverse direction. The leak current Ib in the initial stand-by state is a total current flowing toward the bit line BL side, and Ib=(Vset−2Δ)−NbNw is true.

[(3-2) Leak Current in Active Stand-By State of FLA]

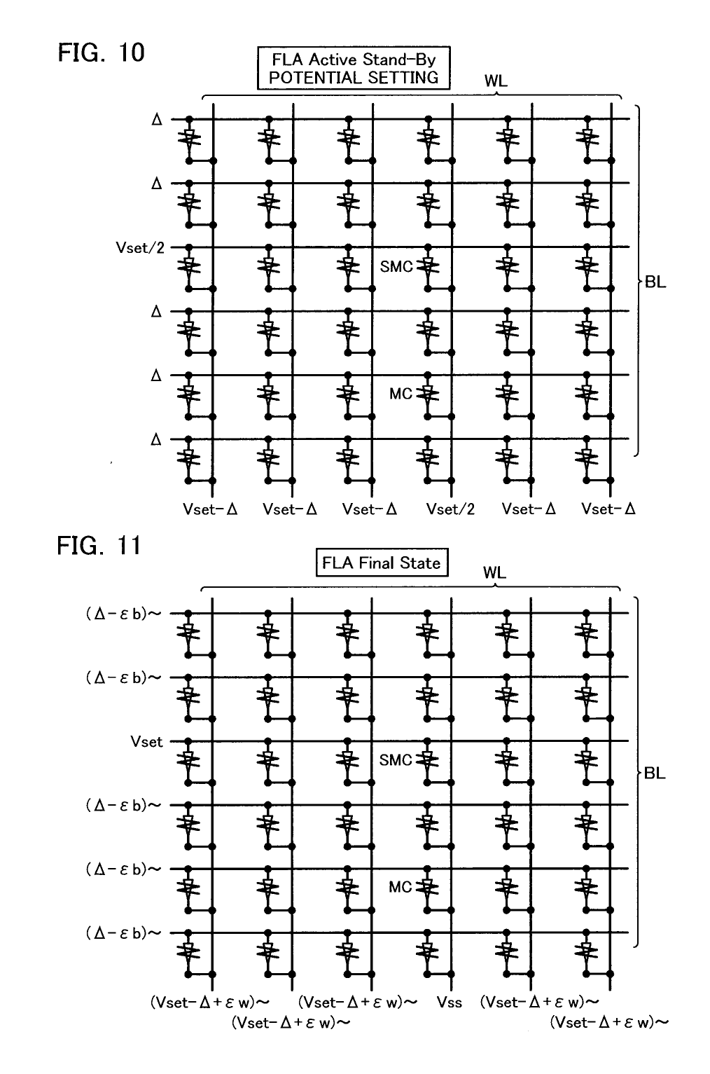

FIG. 10 illustrates a voltage applied to each of the bit lines BL and the word lines WL during the active stand-by operation according to the FLA method. During the active stand-by operation, Vset/2 is applied to the selected bit line BL and the selected word line WL, and the dead-band voltage Δ is applied to the unselected bit lines BL. Further, Vset−Δ is applied to the unselected word lines WL. In addition, the difference between potentials of each bit line BL and word line WL is set by taking into account capacitive coupling occurring between adjacent bit lines BL and between adjacent word lines WL when the active stand-by state transitions to an access state (a electric state of the bit lines and the word lines during the main access operation).

When the voltage is applied to each bit line BL and word line WL, there are (Nb−B) (Nw−1) unselected memory cells MC connected to the unselected bit lines BL and the unselected word lines WL, and a voltage Vset−2Δ is applied to these memory cells MC in a reverse direction. The number of unselected memory cells MC connected to the unselected bit lines BL and the selected word line WL and the number of unselected memory cells MC connected to the selected bit line BL and the unselected word lines WL are Nb−B+(Nw−1)B in total, and the voltage Vset/2−Δ is applied to these memory cells MC in the reverse direction.

Hence, when a total leak current flowing to the bit lines BL is Ib, Ib=r(Vset−2Δ)·(Nb−B)(Nw−1)+r(Vset/2−Δ)·{(Nb−B)+B(Nw−1)}=r(Vset−2Δ)·Nb(Nw−1)+r(Vset/2−Δ)·Nb+{r(Vset/2−Δ)·(Nw−2)−r(Vset−2Δ)·(Nw−1)}B is true. Further, when the total current flowing to the word lines WL is Iw, there is no power supply in the memory mats MM, and Ib+Iw=0 is true. In the active stand-by state, the unselected word line voltage is set higher than the unselected bit line voltage such that a reverse voltage is applied to the memory cells MC connected to the unselected bit lines BL and the unselected word lines WL, and therefore a consumption current component of the leak current is a current Ib flowing from the word line WL side to the bit line BL side. Consequently, it is possible to reduce the leak current by reducing the above Ib.

To reduce the above Ib, it may be possible to set the third term of the above equation to a negative value. For this setting, it may be possible to set r(Vset/2−Δ)·(Nw−2)≦r(Vset−2Δ)·(Nw−1). A function r(x) monotonically increases with respect to x as illustrated in FIG. 8, and, if Vset/2−Δ≦Vset−2Δ is true, that is, if Vset/2≧Δ is true, it is possible to set the third term to a negative value. Further, when the third term is a negative value, it is possible to reduce the leak current when the number of access bit lines B is larger.

In addition, the reverse voltage is applied to all unselected memory cells MC during the stand-by operation, so that the unselected memory cells MC transition from the set state to the weak set state.

In view of above, it is desirable to take the following point into account during the stand-by operation.
(a) When the dead-band voltage Δ≦Vset/2 is true, it is possible to reduce the leak current by increasing the number of access bit lines B.

(b) It is possible to set the unselected memory cells MC from the set state to the weak reset state according to the stand-by operation.

[(3-3) Leak Current in Main Access State of FLA]

FIG. 11 illustrates a voltage applied to the selected bit lines BL and the selected word line WL in the set operation according to the FLA method, and final values of potentials of the unselected bit lines BL and the unselected word lines WL. In the FLA final state, the set voltage Vset is applied to the selected bit lines BL and the ground voltage Vss is applied to the selected word line WL, and the unselected bit lines BL and the unselected word lines WL are set to the floating state. Although, immediately after the voltage is applied, potentials of the unselected bit lines BL and the unselected word lines WL adjacent to the selected bit line BL and the selected word line WL fluctuate due to coupling, these fluctuations of a potentials does not transition the state of the unselected memory cells MC. Then, a current flows to unselected memory cells MC connected to the selected bit lines BL or selected word line WL, and potentials of the unselected bit lines BL and the unselected word lines WL fluctuate. When the voltage which substantially stops a flow of a current to the unselected memory cells MC connected to the unselected bit lines BL and the selected word line WL is Δ−εb, a voltage which substantially stops a flow of a current to the unselected memory cells MC connected to the selected bit lines BL and the unselected word lines WL is Δ−εw and a voltage which is about x is x˜, the potentials of the unselected bit lines BL are (Δ−εb)˜ and the potentials of the unselected word lines WL are (Vset−Δ+εw)˜.

That is, according to the FLA method, the potentials of the unselected bit lines BL stabilize at a voltage which is εb smaller than the dead-band voltage Δ and potentials of the unselected word lines WL stabilize at a voltage which is εw smaller than the dead-band voltage Δ. Variation of the dead-band voltages between the memory cells MC is absorbed by εb and εw in a self-aligning manner. Consequently, it is possible to secure a margin from the dead-band voltage 4 and support individual variations between the unselected memory cells MC.

When the potentials of bit lines BL and word lines WL settle in the above state, there are (Nb−B) (Nw−1) unselected memory cells MC connected to the unselected bit lines BL and the unselected word lines WL, and a voltage Vset−2Δ+εb+εw is applied to these memory cells MC in a reverse direction. Meanwhile, there are Nb−B unselected memory cells MC connected to the unselected bit lines BL and the selected word line WL, and a voltage Δ−εb is applied to these memory cells MC in the forward direction. Further, the number of the unselected memory cells MC connected to the selected bit line BL and the unselected word lines WL is (Nw−1)B in total, and a voltage Δ−εw is applied to each memory cell MC in the forward direction.

Meanwhile, the total leak current flowing to the bit lines BL is Ib, it is only necessary to calculate a reverse leak current flowing to the selected bit line BL in the case of the FLA operation, and Ib=−r(Δ−εw)·B(Nw−1) is true. Further, when the total current flowing to the word lines WL is Iw, it is only necessary to calculate a forward leak current flowing to the selected word lines WL in the same manner, and Iw=r(Δ−εb)·(Nb−B) is true. Furthermore, there is no power supply in the memory mats MM, and Ib+Iw=0 is true. A consumption current flows through the selected bit lines BL or the selected word line WL. Consequently, consumption current I=Iw=r(Δ−εb)·(Nb−B) can be expressed. That is, it is possible to further reduce a consumption current when the number of access bit lines B is larger even in the FLA method.

In addition, Nw−1 unselected word lines WL are connected to each selected bit line BL through the unselected memory cell MC, and a leak current of r(Δ−Eb) flows out from each unselected word line. Hence, a current of r(Δ−sb) (Nw−1) flows out from each selected bit line BL. Consequently, it is possible to reduce noise currents in the selected bit lines BL by reducing Nw.

In view of above, it is desirable to take the following point into account during the access operation according to the FLA method.
(a) It is possible to reduce the leak current by increasing the number of access bit lines B.

(b) It is possible to reduce noise currents by decreasing the total number of word lines Nw. At least, the total number of bit lines Nb may be set larger than the total number of word lines Nw.

(c) According to the FLA method, an applied voltage is determined in a self-aligning manner according to variation of characteristics of the memory cell MC.

[2-1-2. Reduction in Leak Current of Overall Memory Cell Array]

Next, a leak current in the overall memory cell array will be described. Hereinafter, a leak current in case that the bit line BL and the word line WL are individually provided per memory mat MM will be described, and then a leak current in case that only the bit line BL is individually provided per memory mat MM and the word lines WL are shared by the memory mats MM in a plurality of layers.

[(1) Leak Current Upon Separated Bit Lines BL and Separated Word Lines WL Per Memory Mat MM]

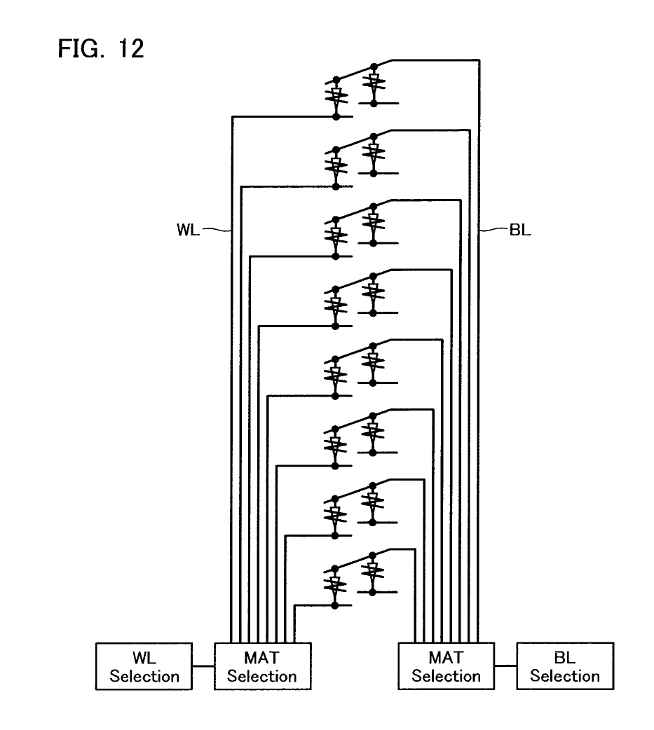

When the bit lines BL and the word lines WL are provided per memory mat MM as illustrated in FIG. 12, each memory mat MM is independent, so that it is possible to maintain the unselected memory mats MM in the hold state during the access operation with respect to the selected memory mat MM, and to ignore the unselected memory mats MM upon calculation of the leak current.

When the word lines WL are provided per memory mat MM, all selector circuits of each memory mat MM are separated on a substrate, and therefore vertical lines and a layout area for connecting the vertical lines become large proportional to the number of stacked memory mats MM. However, the size of one memory mat MM can be increased and, consequently, a selector circuit, a data bus and an address bus may employ a simple configuration.

[(2) Leak Current upon Separated Bit Lines BL per Memory Mat MM and Shared Word Lines WL between a Plurality of Memory Mats MM]

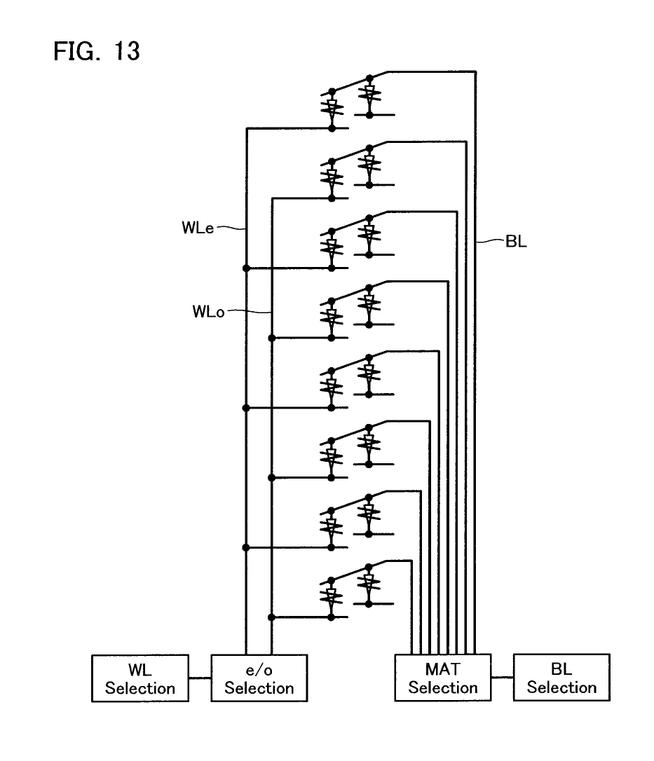

Next, a leak current in case that a plurality of memory mats MM share the word lines WL will be described. Hereinafter, a case will be described as an example where the memory mats MM arranged in even-numbered layers are connected to common word lines WLe and the memory mats MM arranged in odd-numbered layers are connected to common word lines WLo as illustrated in FIG. 13. In addition, it is assumed that 2m memory mats MM are stacked in a stacking direction.

A circuit configuration of sharing the word lines WL between m memory mats MM in this way is the same as a circuit configuration of the memory mat MM the number of bit lines Nb of which is m-fold. That is, a leak current according to such a configuration is equal to a leak current of the memory mat MM having the number of bit lines mNb and the number of word lines Nw.

That is, the current Iw flowing toward the word line side can be expressed as Iw=r(Δ−εb)·(Nb−B)+r(Δ−εb)·(m−1)Nb. Although, similar to the above, the current Ib flowing toward the bit line side can be expressed as Ib=−r(Δ−εw)·B(Nw−1), εw is small and εb is large, thereby satisfying Ib+Iw=0. In addition, a leak current value increases in proportion to the number of memory mats MM m which are virtually standardized.

Further, a current of r(Δ−εw)(Nw−1) flows out from each selected bit line BL. Meanwhile, εw becomes small as described above, and therefore a noise current of each selected bit line BL also increases.

In view of the above, although, when a plurality of memory mats MM share the word lines WL, it is possible to significantly reduce a layout area of word line vertical lines, the size of the memory mats MM needs to be made small inversely proportional to the number of stacked memory mats MM to reduce a leak current and maintain the number of access bit lines, and it is necessary to provide a plurality of memory cell arrays 1 in a chip. Therefore, the number of individual control circuits increases, and lines of a data bus and an address bus become complicated.

[(3) Comparison of Leak Currents Between the Different Configurations]

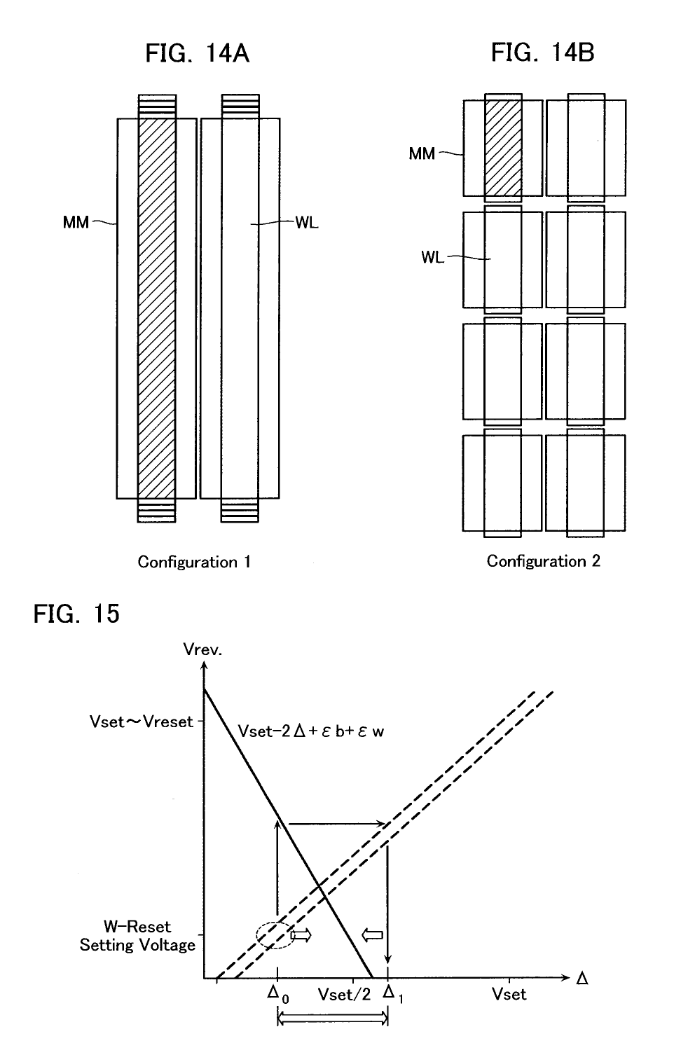

FIGS. 14A and 14B illustrate layouts incase that chips are mounted on a configuration where the bit line BL and the word line WL are independently provided per memory mat MM (referred to as “configuration 1” below) and a configuration where the word lines WL are shared by a plurality of stacked memory mats MM (referred to as “configuration 2” below) such that power consumption is equal. In addition, in FIGS. 14A and 14B, the memory cell arrays are formed by stacking 4 memory mats MM.

Considering the above-described calculation of the lead currents, the size of the memory mat MM according to configuration 1 can be made 4 times larger than that of configuration 2. This is because a shared lines structure described above increases the effective number of bit lines according to the number of stacks in calculation of leak current. Hence, chips having the same memory scales produce a difference between the configurations as illustrated in FIGS. 14A and 14B.

It is possible to increase the number of access bit lines B according to the size of the memory mat MM, so that it is also possible to quadruple a value of the number of the access bit lines B according to configuration 1 compared to the number of the access bit lines B according to configuration 2 and substantially reduce a leak current during the access operation. Further, it is also possible to increase a speed of data access by increasing the number of the access bit lines B.

Meanwhile, although portions of circuits controlling bit lines in a layout of a peripheral circuit do not significantly change, as to the word lines, a layout area around the memory mat MM is increased by the number of stacked memory mats MM when the word lines are provided as separate lines. However, the number of arranged memory mats MM is less than that in configuration 1, so that a total area of the layout does not substantially change. According to configuration 1, circuits are organized in the layout, so that the layout becomes more simple and wasteless.

Summarizing the above, an advanced structure according to the embodiment can be described as follows.

(a) Access operation is performed using the FLA method and the bit lines and word lines are separated per stacked memory mat MM,
(b) the size of the memory mat MM is made as large as possible,
(c) the number of simultaneously selected bit lines is increased and
(d) the number of word lines is made smaller than the number of bit lines.

By this means, it is possible to sufficiently provide an advantage of independently stacked memory mats MM. Although a vertical line circuit becomes large around the memory mat MM in a chip layout in this case, the memory mat MM is also large. Therefore, the number of portions including the vertical line circuit and the memory mat MM becomes smaller and an area ratio in the chip only increases a little. An advantage that a bus configuration becomes simple is also provided.

[2-2. Reduction of Variation of Dead-Band Voltage]

As described above, the dead-band voltage Δ of the memory cell MC varies depending on each memory cell MC. Although the number of memory cells MC remarkably increases when the scale of the memory cell array 1 becomes large, if the dead-band voltage Δ of the memory cell MC included in a given memory mat MM significantly varies in this case, there is a concern that the access operation becomes very difficult. Hence, reducing variation in the dead-band voltage Δ is an important task to increase capacity of the memory cell array.

[(1) Relationship Between Dead-Band Voltage and Reverse Voltage]

FIG. 15 is a graph illustrating a relationship between the dead-band voltage Δ of the memory cell MC and a reverse voltage Vrev for the memory cell MC. In FIG. 15, the vertical axis indicates the reverse voltage Vrev, and the horizontal axis indicates the dead-band voltage Δ. Further, the dead-band voltage Δ fluctuates in a range between lines indicated by two dotted lines according to the reverse voltage Vrev. An increase in the dead-band voltage Δ and the reverse voltage Vrev for the memory cell MC generally have a positive correlation. That is, when a greater reverse voltage Vrev is applied to the memory cell MC, the dead-band voltage Δ increases. Further, the dead-band voltage Δ increases even when time passes. When the reverse voltage Vrev reaches the reset voltage Vreset or when a certain time or more passes, the dead-band voltage Δ takes a value equal to the set voltage Vset and the memory cell MC transition to the reset state. Further, FIG. 15 illustrates a disturb amount Vset−2Δ+εb+εw produced in the unselected memory cell MC during the FLA operation upon a set program. This disturb amount has a negative correlation with respect to the dead-band voltage Δ.

[(2) Fluctuation of Dead-Band Voltage Δ During Access Operation]

Next, fluctuation in the dead-band voltage Δ during the access operation will be described. First, a certain reverse voltage such as Vset−2Δ is applied to the memory cell MC in the memory mat MM upon the access operation to maintain a weak reset state at substantially a certain level. The dead-band voltage Δ takes a predetermined value. A distribution of the dead-band voltage Δ in the memory mat MM is indicated by a range encircled by a dotted line in FIG. 15. Hereinafter, an average value of the dead-band voltage Δ in this case is Δ₀. When the access operation is started and voltages of the unselected bit lines BL and the unselected word lines WL settle, the reverse voltage Vrev=Vset−2Δ+εb+εw is applied to the unselected memory cells MC connected to the unselected bit lines BL and the unselected word lines WL, and the dead-band voltage Δ of the unselected memory cell MC rises. Hereinafter, an average value of dead-band voltages Δ which have been raised by the reverse voltage during the access operation is Δ₁. Meanwhile, according to the FLA method, a voltage greater than Vset−2Δ+εb+εw is not applied to the memory cell MC during the access operation. Hence, according to the FLA method, the dead-band voltage Δ of the memory cell MC in the set state or the weak reset state settles between Δ₀ and Δ₁. When an adequate voltage between Δ₁ and the set voltage Vset is the read voltage Vread, memory cells MC in the weak set state are transitioned to the set state and read, and the memory cell MC in the reset state is read without changing the state. Further, even if the dead-band voltage Δ of the memory cells MC is naturally increased to a voltage from Δ₁ to Vset, the memory cells MC can stay in the weak set state or the set state. Therefore, it is possible to sufficiently secure retention if values of Δ₀ and Δ₁ can be set well.

[(3) Method of Applying Voltage for Reducing Variation of Dead-Band Voltage]

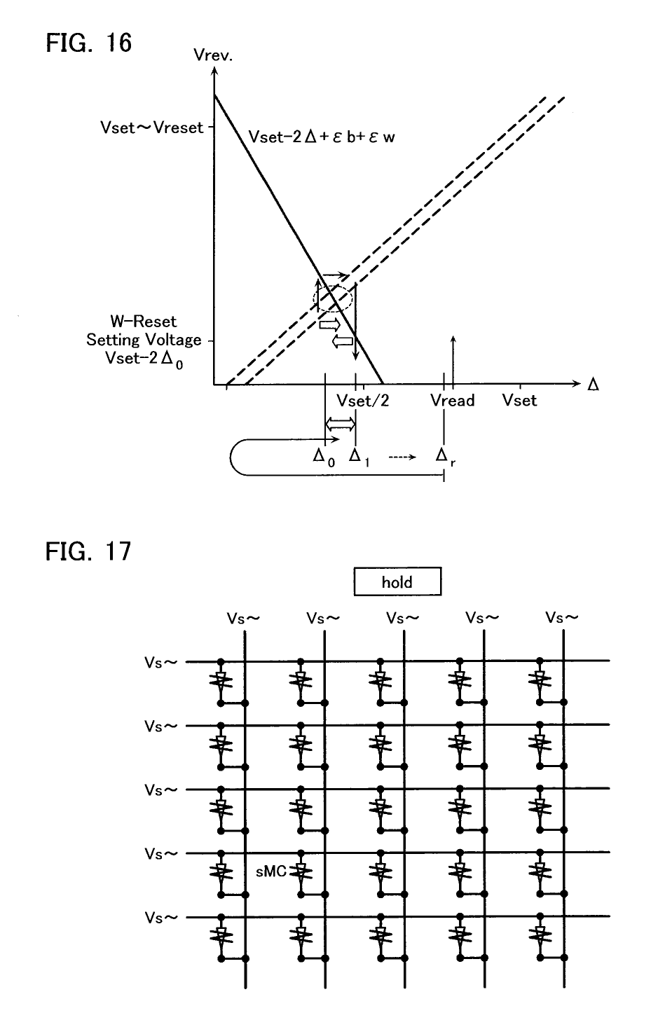

Next, a method of applying the voltage for reducing variation of the dead-band voltage Δ will be described with reference to FIG. 16. To reduce variation of the dead-band voltage Δ produced by applying the reverse voltage Vrev, the above Δ₀ and Δ₁ can be made the same. Further, to prevent an increase in the dead-band voltage Δ following an elapse of time, it is possible to perform a read operation with respect to the memory cell MC or simply apply the read voltage Vread in the forward direction.

Now, an allowable maximum value of the dead-band voltage Δ which is reached by way of natural relaxation is Δᵣ, and the allowable maximum value Δᵣ is set between Δ₁ and the read voltage Vread. When the read voltage Vread is applied to the memory cell MC having the dead-band voltage Δ which reaches Δᵣ, Vread is greater than allowable maximum value Δᵣ, so that it is possible to return the memory cell MC to the set state and set the dead-band voltage Δ to virtually 0V.

Further, the dead-band voltage Δ is set as follows to the memory cell MC which is the set state, by the reverse voltage at a timing of the next access operation.

In initial process of FLA, Vrev=Vset−2Δ is applied, so that the weak reset state of dead-band voltage Δ=Δ₀ is provided again.

In stand-by process, although Vset/2−Δ is applied to the unselected memory cell MC connected to the selected bit line BL, and Vset−2Δ is applied to the other unselected memory cell MC as a reverse voltage. Here, because a reverse bias greater than in the initial process is not applied, states of the memory cells MC are maintained.

In the final state, the reverse bias equal to or less than Vset−2Δ+εb+εw is applied to the unselected memory cell MC, so that dead-band voltage Δ=Δ₁ is set.

Thus, in the FLA process, the relationships of Δ₀≧Δ≦Δ₁ and Vrev≦Vset−2Δ+εb+εw are true. Therefore, to narrow a distribution of the dead-band voltage Δ (to make Δ₀ and Δ₁ virtually the same), the voltage in the initial process can be set such that Vrev=Vset−2Δ is true when the relationship between the reverse voltage Vrev and the dead-band voltage Δ is utilized and εb and εw which are inaccurate amounts are not taken into account.

Summarizing the above, the above-described embodiment is as follows.

(a) In the FLA operation, Δ₁ is determined by Vset−2Δ+εb+εw. By setting reverse voltage Vrev=Vset−2Δ in the initial process in the FLA operation, and increasing Δ₀ as much as possible, a difference between Δ₀ and Δ₁ is canceled.

(b) Passage of time enlarges the dead-band voltage Δ to a voltage exceeding Δ₁ by way of natural transition. However, by applying the read voltage Vread periodically, the dead-band voltage is decreased, and the stored data can be maintained. In the following, the control of the dead-band voltage performed by applying the read voltage Vread periodically is called “refresh process”.

(c) The read voltage Vread can be set larger than Δ₁, and less than Vset. This enables: distinguishing between the set state having an enlarged dead-band voltage Δ and the reset state of the memory cell MC; and setting the dead-band voltage Δ of set state memory cells MC to 0V upon reading in the set state so that the data-retention is improved.

(d) The dead-band voltage Δ of a memory cell to which the refresh process is performed is set between Δ₀ and Δ₁ in the next access cycle.

In addition, when cell data can be corrected by a read ECC (Error Correcting Code), data-retention characteristics of the memory cell MC are reset by rewriting the corrected data, so that it is possible to improve the percentage defective. Then, it is also possible to configure a memory system to write data corrected by the ECC system back to memory cells by embedding the ECC system.

[2-3. Handling of Short-Circuited Memory Cells]

When the scale of the memory mat MM is made larger, the number of defective memory cells MC increases. The defective memory cells MC include memory cells MC in which the filament cannot be connected to the p-type doped polysilicon layer 13 (referred to as “open cells” below), and memory cells MC in which the filament is connected at all times (also referred to as “short-circuited memory cells sMC” below). Although the former causes that the open cells can no longer be used, the latter influences, for example, a setting of potentials of the connected bit lines BL or word lines WL. Hereinafter, a handling method in case that there is short-circuited memory cells sMC in the access target memory mat MM will be described.

[2-3-1. Reduction of Leak Current of Short-Circuited Memory Cells]

To adopt the FLA method for the memory mat MM which includes short-circuited memory cells sMC and preferably perform an access operation, it is effective to apply a common potential ζ to the bit line BL and the word lines WL connected to the short-circuited memory cells sMC. As a result, a leak current is suppressed during the initial stand-by operation and the active stand-by operation due to an influence that the same fixed voltage is applied to the short-circuited memory cells sMC. However, the number of bit lines BL and the word lines WL set to the floating state decrease during the access operation, and a consumption current increases. When the number of bit lines BL connected to a short-circuited memory cells sMC (referred to as “short-circuited bit line” below) is fb, the number of word lines WL connected to a short-circuited memory cells sMC (referred to as “short-circuited word line” below) is fw, a current consumed in the memory mat MM is evaluated and an adequate ζ value is studied. In addition, the total number of bit lines Nb and the total number of word lines Nw include spare lines to which defective lines (short-circuited bit lines BL or short-circuited word line WL) are replaced as described below.

[(1) Leak Current in Hold State]

As illustrated in FIG. 17, in the hold state, all bit lines BL and word lines WL are set to floating state Vs˜ which is virtually the ground potential Vss irrespectively of whether or not there is the short-circuited memory cell sMC. Hence, the leak current in the hold state is not produced.

[(2) Leak Current in Initial Stand-By Operation]

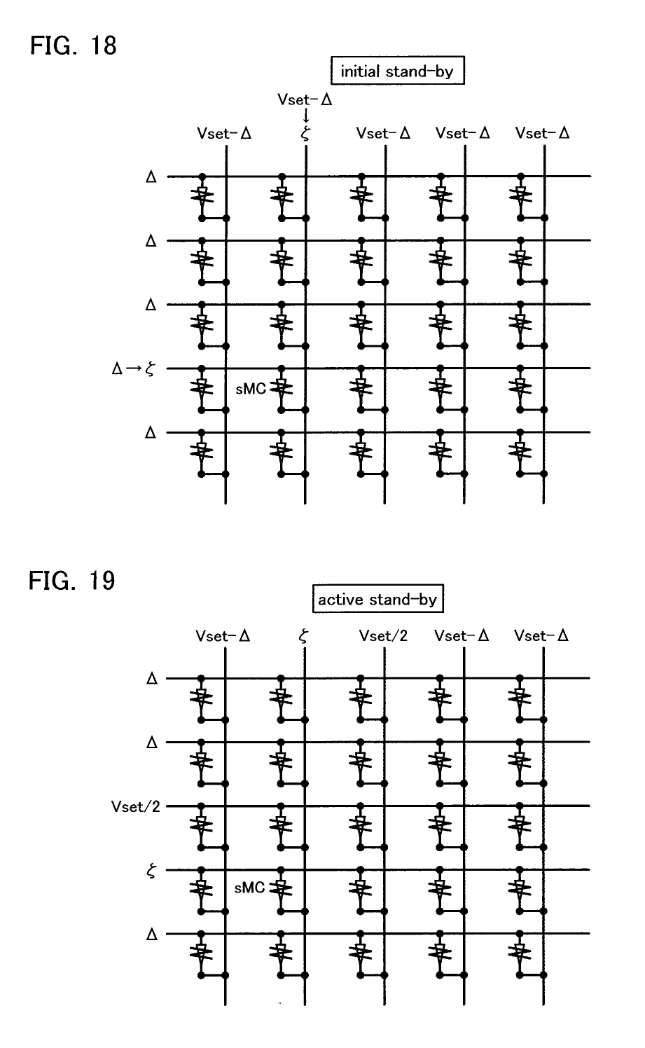

As illustrated in FIG. 18, the dead-band voltage Δ is applied to all bit lines BL and the voltage Vset−Δ is applied to all word lines WL in the initial stand-by operation. By this means, the memory cell MC in the set state transitions to the weak reset state. Further, a short-circuited current flows to the short-circuited bit line BL and short-circuited word line WL, and voltages of the short-circuited bit line BL and the short-circuited word line WL become Z. The fixed potential ζ is immediately applied to the short-circuited bit line BL and the short-circuit word line WL.

Consequently, there are (Nb−fb)·(Nw−fw) memory cells MC connected to normal bit lines BL other than the short-circuited bit lines and normal word lines other than the short-circuited word lines and a voltage Vset−2Δ is applied to each memory cell in the reverse direction, there are (Nb−fb)·fw memory cells MC connected to the normal bit lines BL and the short-circuited word lines and the voltage ζ−Δ is applied to each memory cell in the reverse direction, and there are fb·(Nw−fw) memory cells MC connected to the short-circuited bit lines and normal word lines WL and the reverse voltage Vset−Δ−ζ is applied to each memory cell MC.

Meanwhile, the current Ib flowing toward the bit line side is expressed as Ib=r(Vset−2Δ)·(Nb−fb)·(Nw−fw)+r(ζ−Δ)·(Nb−fb)·fw+r(Vset−Δ−ζ)·fb·(Nw−fw)=r(Vset−2Δ)·Nb·Nw+{r(ζ−Δ)−r(Vset−2Δ)}·(Nb−fb)fw+{r(Vset−Δ−ζ)−r(Vset−2Δ)}·fb(Nw−fw)−r(Vset−2Δ)·fbfw. In addition, there is no power supply in the memory mat MM, and therefore the current Iw flowing toward the word line side is expressed as Iw=−Ib. Further, the reverse voltage is applied to the overall memory mat MM, and therefore the leak current is Ib.

In view of the above equation, the leak current can be reduced by ζ=Vset−Δ is set. By this means, it is possible to set the second term in the above equation to 0 and reduce the third term.

In addition, in the initial stand-by operation, the reverse voltage Vset−2Δ is applied to the memory cells MC which are not connected to the short-circuited bit lines BL nor the short-circuited word lines WL, and the dead-band voltages Δ of these memory cells MC are set to Δ₀ described using FIGS. 15 and 16. However, it is not possible to apply the reverse voltage to the memory cells MC connected to the short-circuited bit lines BL or the short-circuited word lines WL for a sufficient time, and therefore the dead-band voltages Δ of these memory cells MC are smaller than Δ₀. Hence, when there is a short-circuited memory cell sMC in the memory mat MM, variation of the dead-band zone Δ becomes significant, and an increase in the dead-band voltage Δ following an elapse of time is likely to be a problem. It is possible to suitably correct error recognition of such margin data by means of the ECC system.

[(3) Leak Current in Active Stand-By Operation]

In the active stand-by operation, as illustrated in FIG. 19, voltages of the short-circuited bit lines BL and the short-circuited word lines WL are maintained at ζ, the voltage Vset/2 is applied to the selected bit line BL and the selected word line WL, the dead-band voltage Δ is applied to the unselected bit lines BL and the voltage Vset−Δ is applied to the unselected word lines WL.

Hence, there are B·(Nw−1−fw) memory cells MC connected to the selected bit lines BL and the normal unselected word lines WL, and a voltage Vset/2−Δ is applied to each memory cell MC in the reverse direction. Further, there are B·fw memory cells MC connected to the selected bit lines BL and the short-circuited word lines WL, and a voltage ζ−Vset/2 is applied to each memory cell MC in the reverse direction. Furthermore, there are Nb−B−fb memory cells MC connected to the normal unselected bit lines BL and the selected word line WL, and a voltage Vset/2−Δ is applied to each memory cell MC in the reverse direction. Still further, there are (Nb−B−fb)·(Nw−1−fw) memory cells MC connected to the normal unselected bit lines BL and the normal unselected word lines WL, and a voltage Vset−2Δ is applied to each memory cell MC in the reverse direction. Further, there are (Nb−B−fb)·fw memory cells MC connected to the normal unselected bit lines BL and the short-circuited word lines WL, and a voltage ζ−Δ is applied to each memory cell MC in the reverse direction. Furthermore, there are fb memory cells MC connected to the short-circuited bit lines BL and the selected word line WL, and a voltage Vset/2−ζ is applied to each memory cell MC in the reverse direction. Still further, there are fb·(Nw−1−fw) memory cells MC connected to the short-circuited bit lines BL and the normal unselected word lines WL, and a voltage Vset−Δ−ζ is applied to each memory cell MC in the reverse direction.

In view of above, the current Ib flowing toward the bit line side is expressed as Ib=r(Vset/2−Δ)·B·(Nw−1−fw)+r(ζ−Vset/2)·B·fw+r(Vset/2−Δ)·(Nb−B−fb)+r(Vset−2Δ)·(Nb−B−fb)·(Nw−1−fw)+r(ζ−Δ)·(Nb−B−fb)·fw+r(Vset/2−ζ)·fb+r(Vset−Δ−ζ)·fb·(Nw−1−fw). Meanwhile, the current Iw flowing toward the word line side is expressed as Ib=−Iw, and the leak current is expressed as the current Ib flowing toward the bit line side.

Therefore, by setting ζ=Vset−Δ, it is possible to set the seventh term to 0 in the above equation, and reduce a leak current.

[(4) Leak Current During Access Operation]

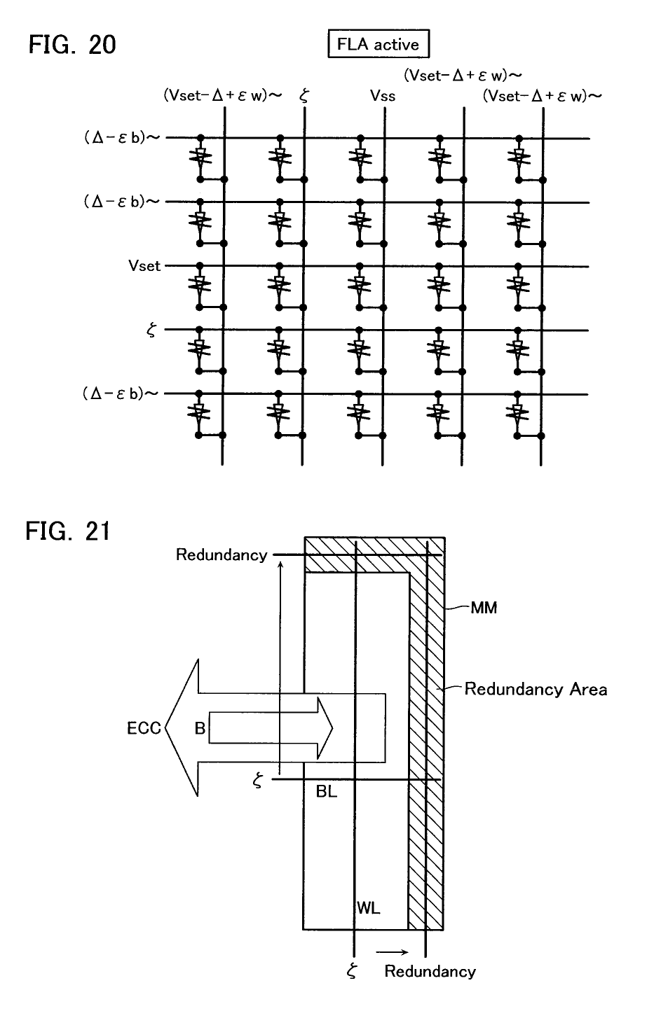

In the active operation, as illustrated in FIG. 20, the set voltage Vset is applied to the selected bit lines BL and the ground potential Vss is applied to the selected word line WL while maintaining potentials of the short-circuited bit lines BL and the short-circuited word lines WL at ζ. Further, the normal unselected bit lines BL other than the short-circuited bit lines BL and the normal unselected word lines WL other than the short-circuited word lines WL are set to the floating state. As a result, the potentials of the normal unselected word lines WL are near Vset−Δ+εw, and the potentials of the normal unselected bit lines BL are near Δ−εb.

Consequently, there are B·(Nw−1−fw) memory cells MC connected to the selected bit lines BL and the normal unselected word lines WL, and a voltage Δ−εw is applied to each memory cell MC in the forward direction. Further, there are B·fw memory cells MC connected to the selected bit lines BL and the short-circuited word lines WL, and a voltage Vset−ζ is applied to each memory cell MC in the forward direction. Furthermore, there are Nb−B−fb memory cells MC connected to the normal unselected bit lines BL and the selected word line WL, and a forward voltage Δ−εb is applied to each memory cell MC in the forward direction. Still further, there are (Nb−B−fb)·(Nw−1−fw) memory cells MC connected to the normal unselected bit lines BL and the normal unselected word lines WL, and a voltage Vset−2Δ−εb−εw is applied in the reverse direction. Further, there are (Nb−B−fb)·fw memory cells MC connected to the normal unselected bit lines BL and the short-circuited word lines WL, and a voltage ζ−Δ+εb is applied to each memory cell MC in the reverse direction. Furthermore, there are fb memory cells MC connected to the short-circuited bit lines BL and the selected word line WL, and a forward voltage ζ is applied to each memory cell MC. Still further, there are fb·(Nw−1−fw) memory cells MC connected to the short-circuited bit lines BL and the normal unselected word lines WL, and a voltage ζ−Vset+Δ−εw is applied to each memory cell MC in the forward direction.

Meanwhile, Ib related to power consumption among currents flowing toward the bit lines BL is a sum of currents flowing toward the selected bit lines BL and short-circuited bit lines BL, and therefore is expressed as Ib=−r(Δ−εw)·B·(Nw−1−fw)−r(Vset−)·B·fw−r(ζ)·fb−r(ζ−Vset+Δ−εw)·fb·(Nw−1−fw). Similarly, Iw related to current consumption among currents flowing toward the word line WL side is a sum of currents flowing toward the selected word line WL and the short-circuited word line WL, and therefore is expressed as Iw=r(Vset+r(Δ—εb)·(Nb−B−fb)−r(−Δ+cb)·(Nb−B−fb)·fw+r(ζ)·fb. There is no power supply in the memory mat MM, and Ib+Iw=0 is true. In view of the above, the leak current is expressed as −Ib=r(Δ−sw)·B·(Nw−1−fw)+r(Vset−ζ)·B·fw+r(ζ)·fb+r(ζ−Vset+Δ−εw)·fb·(Nw−1−fw)=r(Δ−εw)·B·(Nw−1)+fb{r(ζ)+r(ζ−Vset+Δ−εw)·(Nw−1−fw)}+fw·B·{r(Vset−ζ)−r(Δ−cw)}. In addition, the second term and the third term in the above equation are fluctuation of the leak current due to existence of the short-circuited memory cell sMC.

Meanwhile, when the dead-band voltage Δ is Vset/2 or less, Δ≦Vset−Δ≦ζ is true and, if ζ=Vset−Δ is true, it is possible to prevent state transition of the memory cells MC connected to the selected bit lines BL and the short-circuited word lines WL and also prevent state displacement of the memory cells MC connected to the short-circuited bit lines BL and the selected word line WL. Consequently, the leak current is reduced.

Further, although, when a current flows to the memory cells MC connected to the selected bit lines BL and the short-circuited word lines WL, a sense current of the selected bit line BL is influenced and, when ζ=Vset−Δ is true, little current flows to the memory cell MC. Consequently, it is possible to cancel the influence on the sense current due to existence of the short-circuited memory cell sMC.

[2-3-2. Redundancy]

Next, a redundancy in case that there are short-circuited memory cells sMC will be described. FIG. 21 illustrates a configuration of the memory mat MM incase that a redundancy area for replacing the short-circuited memory cells sMC is allocated in the memory mat MM. In addition, how to physically arrange a redundancy area is adequately adjusted.

When the short-circuited memory cells sMC are produced by initial failure caused during manufacturing process, the fixed voltage ζ is applied to the short-circuited bit lines BL and the short-circuited word lines WL as described above, and the bit lines BL and the word lines WL in the redundancy area are used instead. A cross-point memory cell array can be normally accessed upon this replacement because the FLA method is adopted.

Meanwhile, by appropriately writing data in the memory cell MC in which failure occurs due to accumulation of disturb or an elapse of time instead of initial failure, it is possible to use this memory cell MC again. The failure due to, for example, the accumulation of disturb can be suitably improved by restore data utilizing a high speed on-chip ECC system. The restore operation is performed by writing data back by means of the ECC system after data is read. To prevent operation characteristics from being impaired, the ECC system which has a small scale and operates at a high speed can be utilized. In addition, it is conceived that an ion memory which is adopted as the memory cell MC according to the present embodiment is non-volatile, so that performance of the refresh operation using ECC is not significantly impaired.

An example of the ECC system which operates at a high speed uses a BCH code which is capable to correct 2 bits in 144 bits obtained by adding 16 check bits to 128 bits. Such an ECC system is disclosed in, for example, U.S. Pat. Nos. 7,836,377, 7,890,843 and 7,941,733, the entire contents of which are incorporated by reference herein. It is possible to construct a system according to a decode method without using a search solution by way of repetition in the ECC system, and finish error correction in about several tens of ns.

When, for example, a configuration of simultaneous transfer from the memory mat MM is a collective access of data of 64 Bytes, and two ECC systems are provided per 128 bit=16 Byte, are interleaved and utilized in two cycles, ECC processing is finished in 80 ns, and therefore a data transfer rate is 400 MByte/s and no problem is caused.

[2-3-3. Configuration of Sense Amplifier]

As described above, although, in case of ζ=Vset−Δ, little current flows to the memory cells MC connected to the selected bit lines BL and the short-circuited word lines WL and, consequently, it is possible to cancel an influence on a sense current due to existence of the short-circuited memory cell sMC, it is possible to increase precision and a speed of the read operation by further reducing a noise current. Reducing a noise current is realized by a current-comparing sense amplifier (Japanese Patent Application No. 2005-285161). The current-comparing sense amplifier detects a difference between a current flowing to the selected bit line BL and a current flowing to a reference bit line Ref·BL connected to the selected word line WL through the reference memory cell MC. Both of the selected bit line BL and the reference bit line Ref·BL are connected to the selected word line through the memory cell MC, and therefore are influenced in the same way by the sense current due to existence of the short-circuited memory cells sMC. Consequently, this current-comparing sense amplifier cancels a common current component, so that it is possible to further reduce an influence on a sense current due to existence of the short-circuited memory cell sMC. According to such a method, it is possible to detect the state of the selected memory cell SMC reliably at a high speed even upon comparison of currents equal to or less than several 10 nA.

[(1) Basic Configuration of Current-Comparing Sense Amplifier]

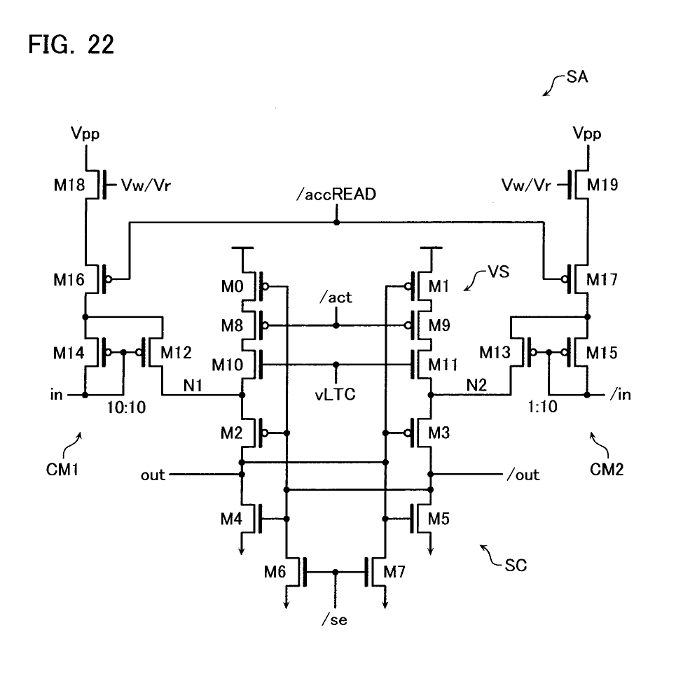

FIG. 22 illustrates a configuration of a current-comparing sense amplifier SA according to the present embodiment. The current-comparing sense amplifier SA according to the present embodiment has a first current mirror circuit CM1 which is connected to the selected bit line BL and outputs a current corresponding to a state of the selected memory cell MC, a second current mirror circuit CM2 which is connected to the reference bit line Ref·BL and outputs a reference current, a voltage-supplying circuit VS which supplies a power-supply in voltage Vdd and a sensing circuit SC which amplifies the difference between the current of the selected bit line BL output from the first current mirror circuit CM1 and a reference current output from the second current mirror circuit CM2.

The first current mirror circuit CM1 is configured to have a NMOS transistor M18 which supplies a voltage according to a signal “Vw” or “Vr” which enters a “H” state upon the set operation or the read operation, a PMOS transistor M16 which is conducted according to a signal “/accREAD”, a PMOS transistor M14 which supplies the supplied power supply voltage to a terminal in and a PMOS transistor M12 which supplies a current equal to the current flowing to the PMOS transistor M14 to a node N1. In addition, the signal “Vw” which enters the “H” state upon the set operation and the signal “Vr” which enters the “H” state upon the read operation have different voltage values, and voltages needed for the operations are supplied according to each operation.

The second current mirror circuit CM2 is configured to have a NMOS transistor M19 which supplies a voltage according to the signal “Vw” or “Vr”, a PMOS transistor M17 which is conducted according to the signal “/accREAD”, a PMOS transistor M15 which supplies the supplied power supply voltage to the terminal /in and a PMOS transistor M13 which supplies a current which is the one tenth of the current flowing to the PMOS transistor M15 to a node N2. The current flowing to the PMOS transistor M13 is the one tenth of the current flowing to the PMOS transistor M15 to use the second current mirror circuit CM2 to supply a reference current to the sense circuit SC. That is, the reference current is used for comparison with the current from the selected bit line BL, and therefore it is necessary to set a lower reference current than the current from the selected bit line BL when the selecting memory cell MC is in the set state and set a higher reference current than the current from the reference bit line Ref·BL when the selecting memory cell MC is in the reset state. In this regard, the reference memory cell MC is set to the set state at all times, and therefore, when the current is set to 1:1, the current from the selected bit line BL and the current from the reference bit line Ref·BL have equal values, and a problem is caused upon detection of the state of the selecting memory cell MC. In addition, the ratio of the current does not need to be the one tenth, and only needs to be set such that a lower current than the current flowing to the selecting memory cell MC in the set state flows to the reference memory cell.

The voltage-supplying circuit VS has PMOS transistors M0 and M1 which have drains connected to a power supply and supply power-supplying voltages Vdd according to potential states of the selected bit line BL and the reference bit line Ref·BL, PMOS transistor M8 and M9 which are connected in series with these PMOS transistors M0 and M1 and are conducted according to a signal “/act”, and NMOS transistors M10 and M11 which are connected in series with these PMOS transistors M8 and M9 and supply voltages corresponding to a signal “vLTC” to the node N1 and the node N2. The voltage-supplying circuit VS is configured by connecting the PMOS transistors M0, M1, M8 and M9 and the NMOS transistors M10 and M11 in series. Hence, a stabilized operation is realized while reducing variation of transistor's electrical characteristics in manufacturing process. Particularly, the NMOS transistors M10 and M11 can contribute to reduction in variations in the electrical characteristics of the PMOS transistors M0, M1, M8 and M9. That is, when a voltage value of the signal “vLTC” input to gates of the NMOS transistors M10 and M11 becomes lower, voltage drop in the NMOS transistors M10 and M11 becomes more significant. Hence, source potentials and drain potentials of the PMOS transistors M0, M1, M8 and M9 rise, and the gate potentials of these PMOS transistors relatively drop, thereby increasing conductances. Such an increase in conductances of the PMOS transistors becomes significant when conductances of the NMOS transistors M10 and M11 become lower, and therefore it is possible to adjust the conductance of a current pathway which is formed with the PMOS transistors M0 and M8 and the NMOS transistor M10 and supplies the voltage to the node N1 and a conductance of a current pathway which is formed with the PMOS transistors M1 and M9 and the NMOS transistor M11 and supplies the voltage to the node N2. With the present embodiment, upon comparison of a current flowing to the selected bit line BL and a current flowing to the reference bit line Ref·BL, it is possible to set the signal “vLTC” to a low voltage VRR to supply a precise voltage, set “vLTC” to a high voltage VPP after magnitudes of currents are determined and latch determined data at a high speed. In addition, it may be possible to set the voltage VRR between the ground potential Vss and a power supply voltage potential Vdd, and set the voltage VPP larger than the power-supplying voltage Vdd.

The sensing circuit SC has the PMOS transistors M2 and M3 and the NMOS transistors M4 and M5 which have one ends of output terminals “out” and “/out” connected to the node N1 or the node N2 according to the state of the selected bit line BL and have the other ends connected to the ground terminal, and the NMOS transistors M6 and M7 which connect the selected bit line BL or the reference bit line BL to the ground terminal according to a signal “/se”.

[(2) Basic Operation of Current-Comparing Sense Amplifier]

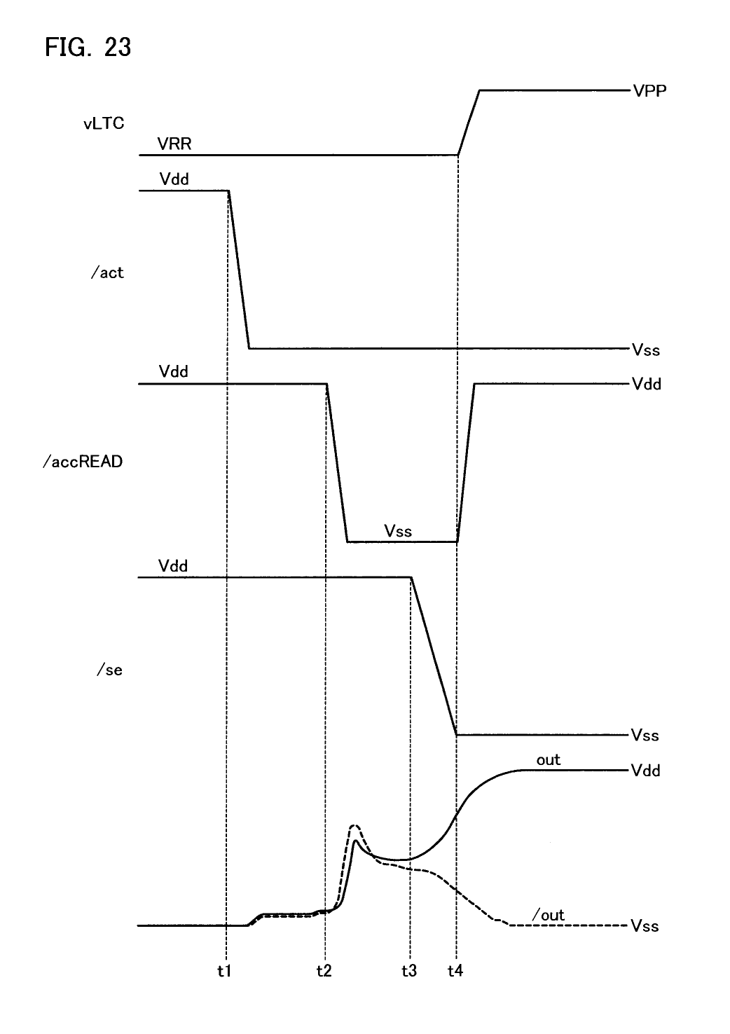

FIG. 23 is a voltage waveform diagram for explaining a control signal and an output signal of the current-comparing sense amplifier circuit. In the initial state of the current-comparing sense amplifier, the signal “/accREAD”, the signal “/act” and the signal “/se” are all set to the “H” state, thereby blocking a power supply to a current-comparing sense amplifier SA. Further, a voltage value of the signal “vLTC” is set to low. However, the voltage value of the signal “vLTC” is set enough to set the NMOS transistors M10 and M11 conductive state.

When a read operation is started, the signal “/act” is set to a “L” state at a timing t1, and a supply of the power-supplying voltage Vdd is started by the voltage-supplying circuit VS. The output terminals out and /out are grounded through the NMOS transistors M6 and M7 and the PMOS transistors M0, M1, M2 and M3 are conducted, and NMOS transistors M10 and M11 is conducted. Therefore, the output terminals out and /out receive a supply of the voltage.

At a timing t2, the signal “/accREAD” is set to “L” state, and power is supplied to the first current mirror circuit CM1 and the second current mirror circuit CM2. The current supplied to the first current mirror circuit CM1 flows to the selected bit line BL through the PMOS transistor M14 and the terminal in. Further, a detected current having the same magnitude as the current flowing to this selected bit line BL is supplied to the sensing circuit SC through the PMOS transistor M12 and the node N1. Similarly, the current supplied to the second current mirror circuit CM2 flows to the reference bit line Ref·BL through the PMOS transistor M15 and the terminal /in. Further, a reference current having the one tenth of the magnitude as the current flowing to this reference bit line Ref·BL is supplied to the sensing circuit SC through the PMOS transistor M13 and the node N2. The detected current raises the potential of the output terminal out, and the reference current raises the potential of the output terminal /out. However, when the potential of the output terminal out reaches a certain level, a supply of the reference current to the output terminal /out is restricted by the PMOS transistor M3, and, similarly, even when the potential of the output terminal /out reaches a certain level, a supply of a detection current to the output terminal out is also restricted by the PMOS transistor M2. Hence, when a predetermined time passes, a potential difference is produced between the output terminals out and /out. In addition, although the node N1 and the node N2 receive a supply of voltages from the first current mirror circuit CM1, the second current mirror circuit CM2 and the voltage-supplying circuit VS, the signal “vLTC” is set to a low voltage as described above, and therefore the potentials of the node N1 and the node N2 are mainly adjusted by the first and second current mirror circuits CM1 and CM2.

At a timing t3, a voltage value of the signal “/se” gradually drops. As a result, operating points of the NMOS transistors M6 and M7 move from a linear area to a saturated area, and a minute difference between currents flowing to the NMOS transistors M6 and M7 is converted into a difference of a significant voltage drop. In addition, between the timings t2 and t3, a time in which currents flowing to the selected bit line BL and the reference bit line Ref·BL require to become currents which sufficiently reflect the states of the selecting memory cell MC and the reference memory cell MC needs to be provided.

At a timing t4, by raising the voltage value of the signal “vTLC” and increasing an output of the voltage-supplying circuit VS, and raising the signal “/accREAD”, a supply of currents to the first current mirror circuit CM1 and the second current mirror circuit CM2 is stopped. By this means, a supply of a current to the sensing circuit SC is switched to the voltage-supplying circuit VS, and a potential difference between the output terminals out and /out is further emphasized.

[2-3-4. Reduction of Short-Circuited Cell Occurrence]

Next, means for preventing a short-circuited cell from being newly produced will be described. When a forward voltage is continuously applied to the memory cell MC in the set state, there is a concern that an excessively set state is provided where the filament of the memory cell MC is completely connected. The memory cell MC in the excessively set state is short-circuited at all times, and does not enter the reset state even by being applied the reverse voltage.

[(1) Sensing System Using Current-Comparing Sense Amplifier]

Production of a new short-circuited cell can be reduced by making a device of the sensing system. Hereinafter, such a sensing system will be described.

[(1-1) Configuration of Sensing System Using Current-Comparing Sense Amplifier]

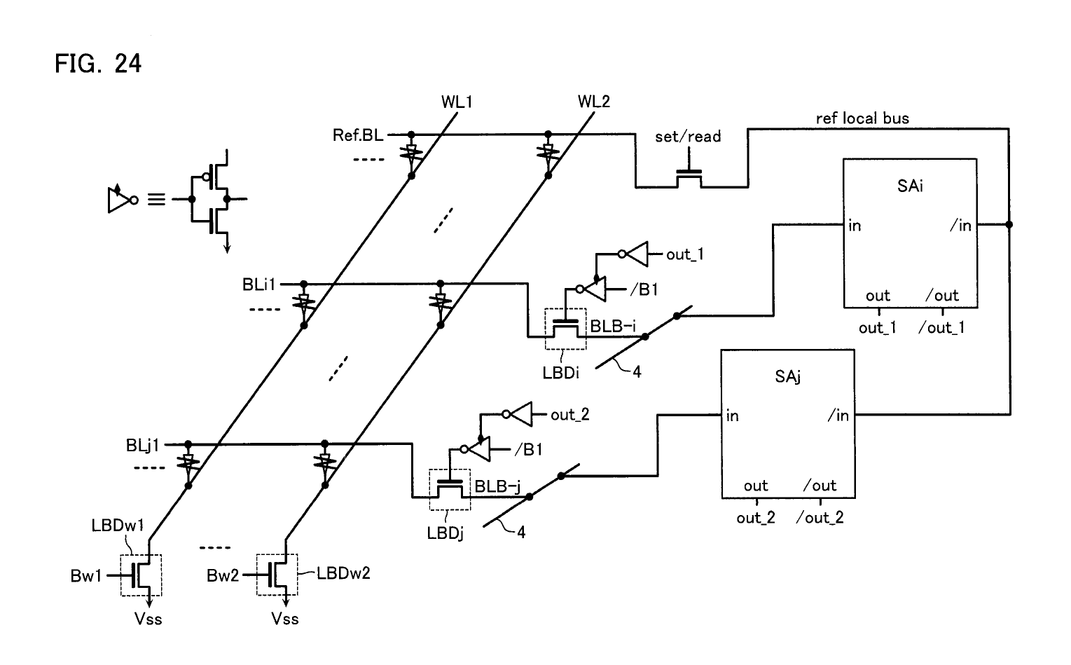

FIG. 24 is a circuit diagram illustrating an example of a multibit simultaneous accessinf system. In the multibit simultaneous accessing system according to the present embodiment, potential states of a plurality of selected bit lines BL are detected referring to the common reference bit line Ref·BL.

As described above, a plurality of bit lines BL configure the bit line block BLB, and one bit line BL is selected as the selected bit line BL from each bit line block BLB by a selecting line block decoder LBD. The selected bit line BL is connected to the current-comparing sense amplifier SA provided per bit line block BLB through a BL switch and the data bus 4 in the selecting line block decoder LBD. The BL switch in FIG. 24 is a NMOS transistor configuring a selector unit 21a of the selecting line block decoder LBD illustrated in FIG. 6.

The BL switch is configured to connect the selected bit line BL to the current-comparing sense amplifier SA according to an address signal “/B1”, and block connection between the selected bit line BL1 and the current-comparing sense amplifier SA when the current-comparing sense amplifier SA detects that the selecting memory cell MC is in the set state. Although, when the forward voltage is continuously applied to the memory cell MC in the set state, there is a concern that the memory cell MC enters the excessively set state in which the memory cell MC is short-circuited at all times, short-circuiting is prevented by the configuration according to the present embodiment. Further, it is also possible to reduce power consumption in the selecting memory cell MC. In addition, the bit line BL can also be blocked by operating the signal “/actREAD” of the current-comparing sense amplifier SA.

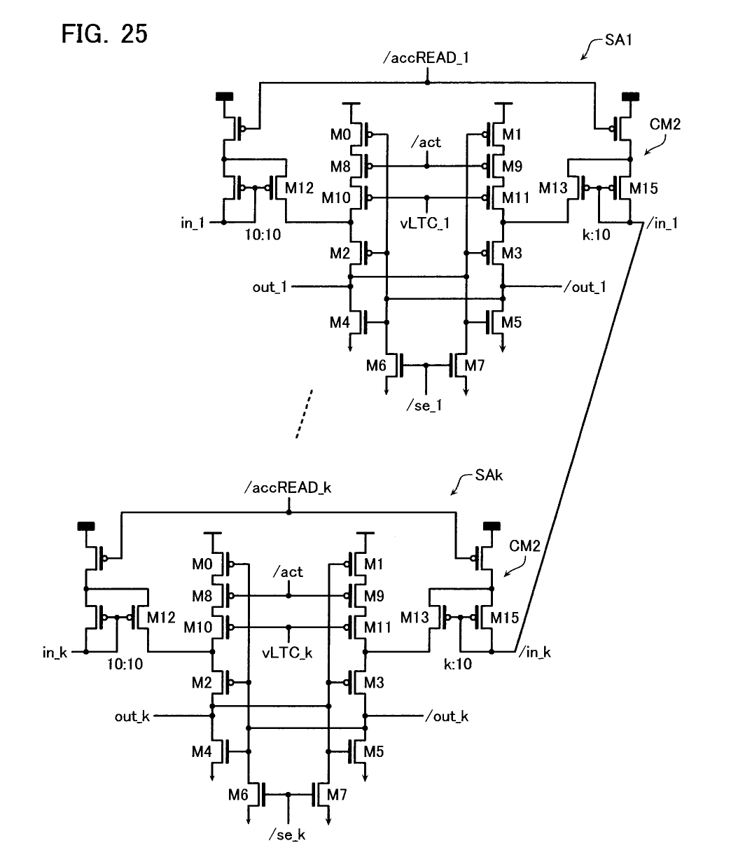

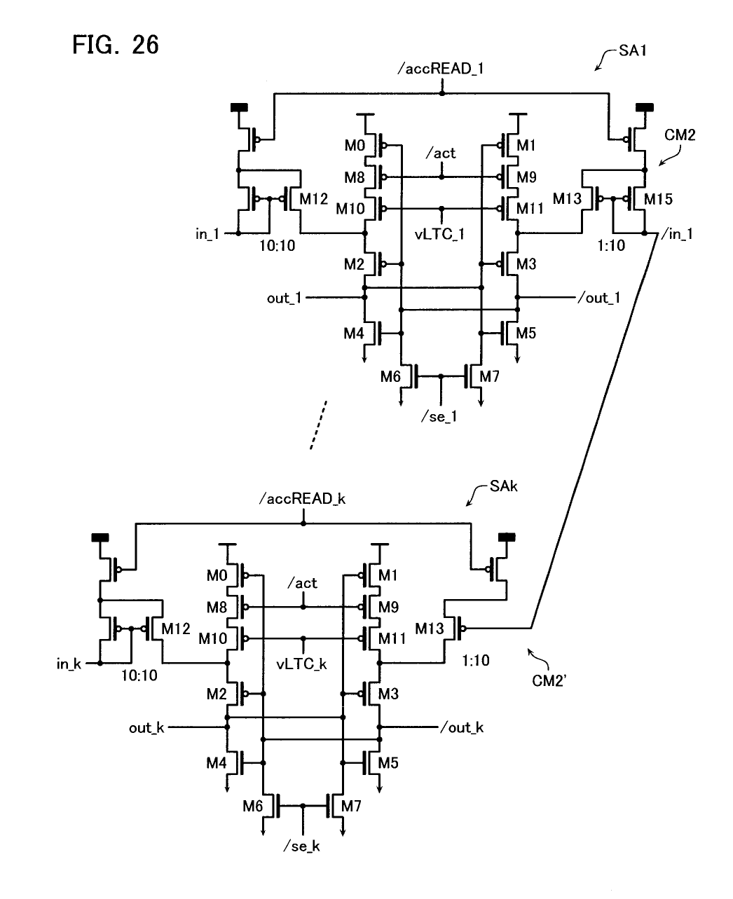

The reference bit line Ref·BL is also connected to the BL switch. The BL switch is commonly connected to a plurality of current-comparing sense amplifiers and the reference bit lines Ref·BL through a reference local bus upon the set operation and the read operation. In addition, when the reference bit line Ref·BL is connected to k current-comparing sense amplifiers, a current flowing from each current-comparing sense amplifier SA to the reference bit line Ref·BL is 1/k-fold. Hence, as illustrated in FIG. 25, the ratio of the current amount of the second current mirror circuit CM2 included in each current-comparing sense amplifier SAmay be adjusted to k:10. Further, as illustrated in FIG. 26, one current-comparing sense amplifier circuit SA may be configured as conventionally configured, and configurations of k−1 current-comparing sense amplifier circuits SA may be removed. That is, the PMOS transistor M15 configuring the second current mirror circuit CM2 is removed from the k−1 current-comparing sense amplifier circuits to make a second current mirror circuit CM2′. In case of such a configuration, the ratio of current amounts of the current mirror circuits CM2 and CM2′ only needs to be kept as 1:10.

As described above, the word lines WL are connected to the selecting line block decoder LBD, and the selected word line WL and the ground terminal are connected according to an address signal “B”.

[(1-2) Operation of the Sensing System Using Current-Comparing Sense Amplifier]

Next, an operation of the sensing system will be described using the set operation and a verify operation as examples. In the memory mat MM, voltage values for transitioning the memory cells MC to the set state has variation. Hence, when the set voltage Vset to be uniformly applied to the memory cell MC is determined, if the set voltage Vset is set low, there are a plurality of memory cells MC which do not transition to the set state, and there is a concern that, if the set voltage is set high, a plurality of memory cells MC are transition to the excessively set state.

According to the present embodiment, to overcome the above problem, the set voltage Vset is set low first and the set voltage Vset is gradually increased. Further, a time for applying the voltage, that is, a pulse width may be increased. It is possible to increase not only one of the set voltage Vset and the pulse width but also both. In this process, when the memory cell MC enters the set state, the set state is detected, and application of the voltage to the bit line BL connected to the memory cell MC which has transitioned to the set state is finished.

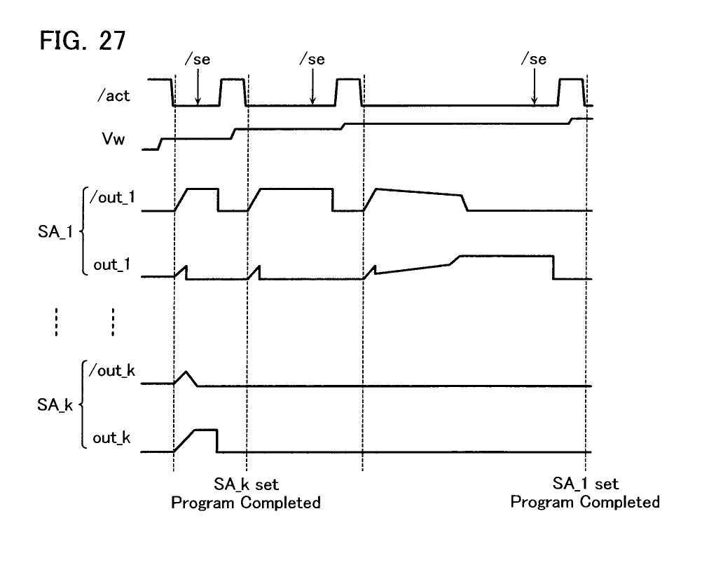

FIG. 27 is a voltage waveform diagram illustrating a state of a voltage of the set operation according to the present embodiment. When the set operation is started, the signal “Vw” rises first, and a power supply to each current-comparing sense amplifier SA and the selected bit line BL is started. Next, the signal “/act” is set to the “L” state, and detection of the voltage of the selected bit line BL is started. After a predetermined time passes, the signal “/act” is set to the “H” state, and a first write cycle is finished.

Meanwhile, when, for example, the selected memory cell SMC connected to a sense amplifier SA_k among k current-comparing sense amplifiers SA transitions to the set state in the first write cycle, an output signal “out_k” of the current-comparing sense amplifier SA_k rises, and the BL switch which connects the selected bit line BL and the current-comparing sense amplifier SA-k transition to the off state.

When all selected memory cells SMC do not transition to the set state in the first write cycle, the second write cycle is performed. In the second write cycle, the set voltage Vset may be increased by, for example, increasing the signal “Vw”. Further, the pulse width may also be increased by increasing a time for holding the signal “/act” in the “L” state.

Subsequently, the write cycle is repeated in the same manner, and the set operation is finished at a timing when output signals “out” of all current-comparing sense amplifiers SA rise. When, for example, the selected memory cells MC connected to all sense amplifiers SA transition to the set state in the third cycle, the write cycle is finished in the third cycle.

[(2) Multibit Simultaneous Accessing System Using Serial Resistance]

As described above, the sensing system blocks a current pathway between the selected bit line BL and the current-comparing sense amplifier SA according to the output signal out of the current-comparing sense amplifier SA, and thereby reduces production of the short-circuited memory cell sMC. However, this method cannot prevent production of the short-circuited memory cell sMC which is produced earlier than a response speed of a circuit. Hereinafter, a countermeasure for handling such high speed production of the short-circuited memory cell sMC will be described.

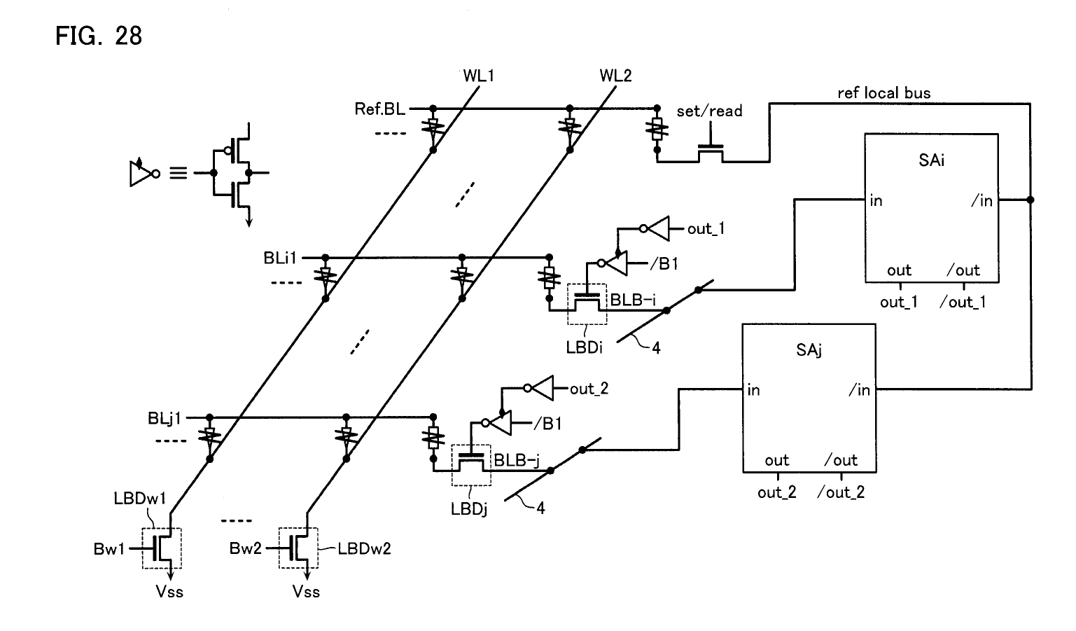

As illustrated in FIG. 28, to reduce high speed production of a short-circuit memory cell sMC, a serial resistance SR may be provided between the selecting line block decoder LBD and each bit line BL. According to such a configuration, an overcurrent with respect to the memory cells MC which has transitioned to the set state is prevented, so that it is possible to reduce high speed production of the short-circuited memory cell sMC. Further, resistances are inserted into the bit lines BL, so that it is possible to alleviate propagation of a disturb potential produced in each bit line BL, and expect a more precise access operation at a higher speed.

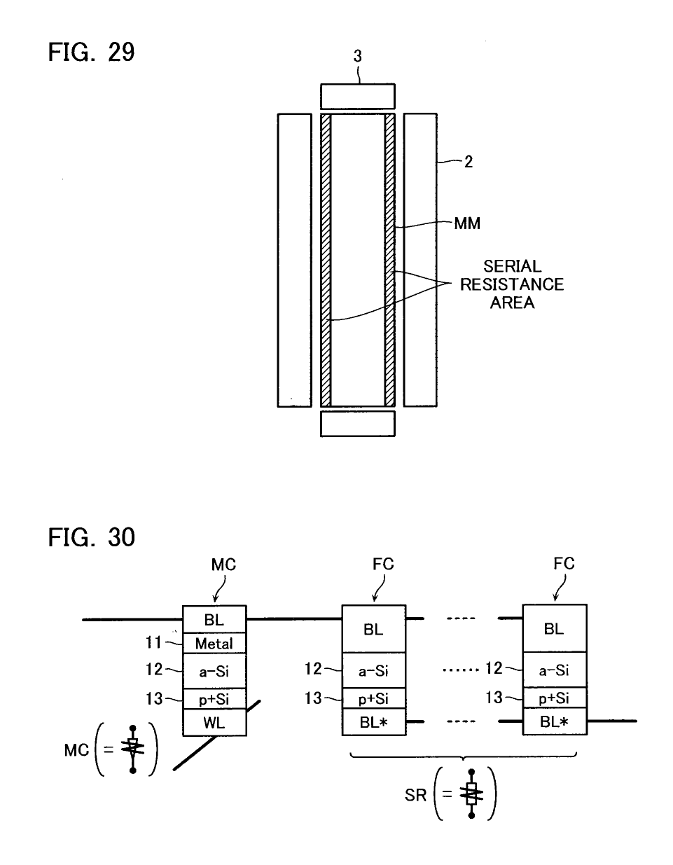

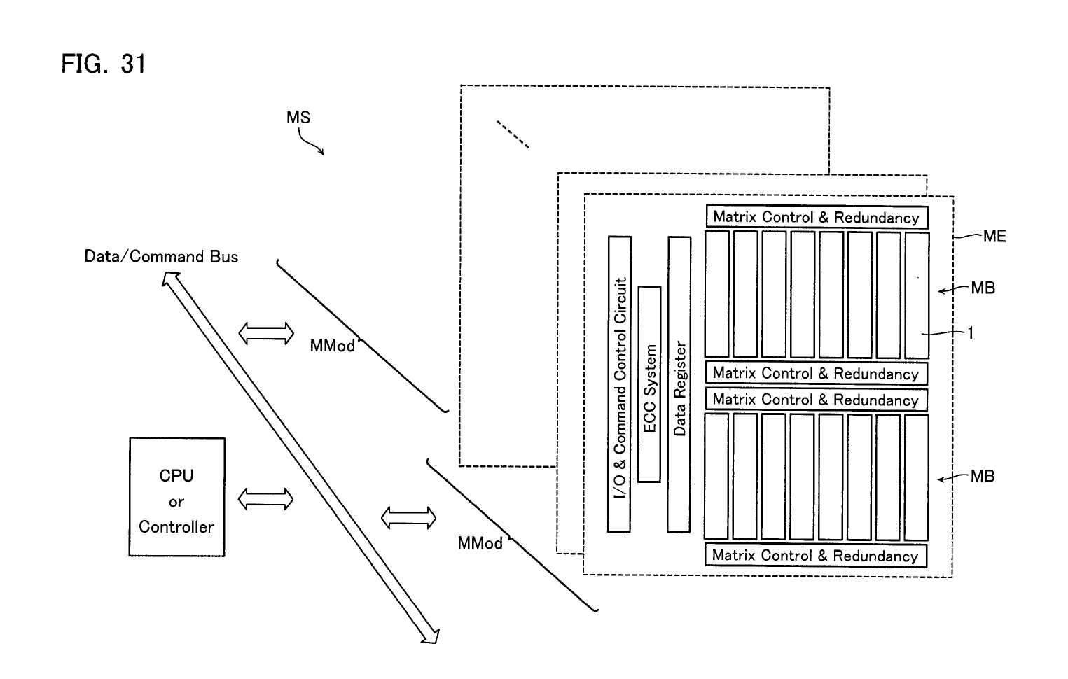

When a configuration of leading the bit lines BL from both ends of the memory mat MM is employed, the serial resistance SR is provided in areas at both ends on the column control circuit 2 of the memory mat MM (referred to as “serial resistance areas” below) as indicated by shaded areas in FIG. 29. Further, the serial resistance SR can be fabricated utilizing the element structure of the memory cell MC. That is, as illustrated in FIG. 30, a plurality of pseudo cells FC are fabricated by removing the metal layers 11 of the memory cells MC arranged in the serial resistance areas in the memory mat MM, and a plurality of pseudo cells FC are connected in parallel to provide the serial resistance SR. Further, portions of the word lines WL corresponding to the a plurality of pseudo cells FC aligned in the bit line BL direction is divided in the row direction, and is commonly connected in the column direction to provide the bit lines BL*. Consequently, the bit lines BL are connected to the bit lines BL* through the plurality of pseudo cells FC configuring the serial resistance SR. Such a configuration can be realized only by using a mask which covers the serial resistance areas upon formation of the metal layers 11. Further, the resistance value of the serial resistance SR can be adequately adjusted by adjusting the number of pseudo cells FC. The configuration of the memory cell MC is utilized, so that a substantially great number of pseudo cells FC can be aligned.

Only one memory cell MC is accessed in each bit line BL, and has one serial resistance in the access operation. By providing the serial resistance SR in addition to the memory cell MC, the resistance is easily adjusted, thereby effectively restricting the current.

[3. Memory System]

Various problems resulting from an increase in memory size of the memory cell array, that is, a problem of the leak current, a problem of variation in the dead-band voltage Δ and a problem of the short-circuited memory cells sMC, and a configuration and a method for solving these various problems have been described above. Hereinafter, an example of the memory system utilizing these configuration and method will be described.

A memory system MS has a CPU or a controller, a data/command bus and a plurality of memory modules MMod which are each connected to the data command bus. A file memory sends and receives signals and data directly to or from the CPU or the data/command bus through the controller. Further, the memory module MMod holds data in a non-volatile state even if data is separated from the memory system MS and stored. Furthermore, the memory system MS can access a new data group by replacing the memory module MMod.

A plurality of memory modules MMod each have a plurality of memory elements ME. The plurality of memory elements ME have two memory banks MB configured by a plurality of memory cell arrays 1. The memory cell arrays 1 in the memory bank MB can operate independently from the memory cell arrays 1 in the other memory bank MB. Further, a plurality of memory elements ME has a matrix/control & redundancy, an I/O & command control circuit, an ECC system and a data register provided to each of the two memory banks MB. The matrix control & redundancy and the ECC system manage and control the ECC and redundancy according to characteristics of individual memory cells MC.

[Other]

While certain embodiments have been described, these embodiments have been presented by way of example only, and are not intended to limit the scope of the inventions. Indeed, the novel methods and systems described herein may be embodied in a variety of other forms: furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. (canceled)

2. A semiconductor memory device comprising:
a memory cell array which comprises a memory mat which comprises a plurality of first lines, a plurality of second lines intersecting with the first lines and a plurality of resistance varying memory cells provided at intersection portions of the pluralities of first lines and second lines; and
an accessing circuit which accesses selected memory cells by applying voltages to the memory cell array,
a number of the first lines included in the memory mat being greater than a number of the second lines,
when the accessing circuit accesses the selected memory cells, the accessing circuit selecting a plurality of first lines and a second line connected to the selected memory cells to which the accessing circuit needs to be connected and judging data stored in the selected memory cells according to currents flowing to the selected memory cells,
at an end of the memory mat, a serial resistance being provided which is connected to a first line and is formed in a same layer as the memory cell in a same manner as the memory cell, and
the first line and the accessing circuit being connected through the serial resistance.

3. The semiconductor memory device according to claim 2, wherein:
the memory cell array is configured by stacking the plurality of memory mats; and
the accessing circuit independently controls per memory mat the first lines and the second line which the accessing circuit needs to access.

4. The semiconductor memory device according to claim 2, wherein
the memory cells show non-ohmic characteristics,
states of the memory cells are capable of transitioning between a first state and a second state in which a resistance value of the memory cell is higher than a resistance value of the memory cell in the first state, and
when: a direction from the first lines to the second lines is a forward direction; a direction from the second lines to the first lines is a reverse direction; and a voltage which does not make the states of the memory cells transition even if the voltage is applied to the memory cells in the forward direction is a dead-band voltage Δ, the dead-band voltage Δ changes by applying a voltage in the reverse direction.

5. The semiconductor memory device according to claim 4, wherein the accessing circuit executes a floating access which set a state of the first lines and the second lines which are not connected to the selected memory cells to a floating state at a final stage of an access.

6. The semiconductor memory device according to claim 5, wherein:
when a third state of the memory cells is a state from which: the memory cells can easily transition to the first state; and is an intermediate state of the first state and the second state, the memory cells can transition from the first state to the third state by applying the voltage in the reverse direction; and
the accessing circuit makes the memory cells transition to the third state at an initial stage of the floating access.

7. The semiconductor memory device according to claim 4, wherein, when the first state is a set state and a set voltage for making the memory cells transition to the set state is Vset, a relationship of Vset/2≧Δ holds.

8. The semiconductor memory device according to claim 4, wherein,
when the first state is a set state, a set voltage for making the memory cells transition to the set state is Vset, a reading voltage for reading the memory cells is Vread and an average value of dead-band voltages of unselected memory cells after the set operation is Δ1, the reading voltage Vread is set between Δ1 and Vset.

9. The semiconductor memory device according to claim 4, wherein, when the first state is a set state: a set voltage for making the memory cell transition to the set state is Vset; a reading voltage for reading the memory cell is Vread; an average value of dead-band voltages of the unselected memory cells after the set operation is Δ1; and an average value of the dead-band voltages upon application of reverse direction voltage Vset−2Δ to all memory cells in the memory mat is Δ0, a voltage in initial process is set such that Δ0 and Δ1 virtually match.

10. The semiconductor memory device according to claim 4, wherein:
data read from the memory cell is error-corrected by an ECC (Error Correction Code) system; and
the accessing circuit writes the error-corrected data back to the memory cell.

11. The semiconductor memory device according to claim 2, wherein, when there is a short-circuited memory cell in the memory mat, the accessing circuit sets potentials of a first line and a second line connected to the short-circuited memory cell to a same fixed potential.

12. The semiconductor memory device according to claim 2, wherein a redundancy area is provided in the memory mat, and, when there is a short-circuited memory cell in the memory mat, the first line and the second line connected to the short-circuited memory cell are replaced with an arbitrary first line and second line in the redundancy area.

13. The semiconductor memory device according to claim 2, wherein:
the memory mat comprises a reference memory cell; and
the accessing circuit comprises a current-comparing sense amplifier which compares a current flowing to a plurality of first lines connected with a plurality of selected memory cells and a current flowing to a reference line which is a first line connected through the reference memory cell to a second line to which the selected memory cells are commonly connected and detects the state of the selected memory cells.

14. The semiconductor memory device according to claim 2, wherein:
the memory cell is formed between the first lines and the second lines to comprise a silicon layer and a metal layer in contact with the silicon layer; and
the serial resistance comprises a pseudo cell including a polysilicon layer formed between the first lines and a third line formed in a same layer as the second lines, and the pseudo cell not including the metal layer.

15. The semiconductor memory device according to claim 14, wherein:
the serial resistance is configured by connecting a plurality of pseudo cells in parallel;
ends of the plurality of pseudo cells configuring a serial resistance are commonly connected to the first line; and
other ends of the plurality of pseudo cells configuring the serial resistance are commonly connected to the third line.

16. A semiconductor memory device comprising:
a memory cell array which is formed by stacking through insulation layers a plurality of memory mats which comprises a plurality of first lines, a plurality of second lines intersecting with the first lines and a plurality of resistance varying memory cells provided at intersection portions of the pluralities of first lines and second lines; and an accessing circuit which accesses selected memory cells by applying voltages to the memory cell array,
the memory cell array being configured by stacking the plurality of memory mats,
when the accessing circuit accesses the selected memory cells, the accessing circuit selecting a plurality of first lines and a second line connected to the selected memory cells to which the accessing circuit needs to be connected and judging data stored in the selected memory cells according to currents flowing to the selected memory cells,
at an end of the memory mat, a serial resistance being provided which is connected to a first line and is formed in a same layer as the memory cell in a same manner as the memory cell, and
the first line and the accessing circuit being connected through the serial resistance.

17. The semiconductor memory device according to claim 16, wherein
the memory cells show non-ohmic characteristics,
states of the memory cells are capable of transitioning between a first state and a second state in which a resistance value of the memory cell is higher than a resistance value of the memory cells in the first state, and
when: a direction from the first lines to the second lines is a forward direction; a direction from the second lines to the first lines is a reverse direction; and a voltage which does not make the states of the memory cells transition even if the voltage is applied to the memory cells in the forward direction is a dead-band voltage Δ, the dead-band voltage Δ changes by applying a voltage in the reverse direction.

18. The semiconductor memory device according to claim 17, wherein the accessing circuit executes a floating access which set states of the first lines and the second lines which are not connected to the selected memory cells to a floating state at a final stage of an access.

19. A file memory system comprising:
a plurality memory modules; and
a controller which controls the memory modules,
the memory modules each comprising:
a memory cell array which comprises a memory mat which comprises a plurality of first lines, a plurality of second lines intersecting with the first lines and a plurality of resistance varying memory cells provided at intersection portions of the pluralities of first lines and second lines; and
an accessing circuit which accesses selected memory cells by applying voltages to the memory cell array;
a number of the first lines included in the memory mat being greater than a number of the second lines;
when the accessing circuit accesses the selected memory cells, the accessing circuit selecting a plurality of first lines and a second line connected to the selected memory cells to which the accessing circuit needs to be connected and judging data stored in the selected memory cells according to currents flowing to the selected memory cells,
at an end of the memory mat, a serial resistance being provided which is connected to a first line and is formed in a same layer as the memory cell in a same manner as the memory cell, and
the first line and the accessing circuit being connected through the serial resistance.

20. The file memory system according to claim 19, wherein:
the memory module comprises an ECC (Error Correction Code) system which error-corrects data read from the memory cell; and
the accessing circuit writes the data error-corrected by the ECC system back to the memory cell.
